(19) United States
(12) Patent Application Publication
(10) Pub. No.: US 2025/0355801 A1
(43) Pub. Date: Nov. 20, 2025

(54) MEMORY SYSTEM AND METHOD FOR IMPLEMENTING MULTI-LEVEL SIGNALING IN MEMORY INTERFACE

(71) Applicant: Samsung Electronics Co., Ltd., Suwon-si (KR)

(72) Inventors: Anil Kavala, Suwon-si (KR); Youngmin Jo, Suwon-si (KR); Chiweon Yoon, Suwon-si (KR); Cheolhui Lee, Suwon-si (KR)

(21) Appl. No.: 19/209,890

(22) Filed: May 16, 2025

(30) Foreign Application Priority Data
May 17, 2024 (KR) 10-2024-0064805

(51) Int. Cl. G06F 12/02

(52) U.S. Cl. CPC G06F 12/0246; G06F 2212/7203

(57) ABSTRACT

A memory system includes a first memory device outputting a first data signal through a first data pin, a second memory device outputting a second data signal through a second data pin, a memory controller controlling the first and second memory devices, a buffer chip connected between the memory controller and each of the first and second memory devices, and a first signal line connecting the buffer chip to each of the first and second data pins. The buffer chip comprises a receiver circuit receiving a multi-level signal from the first signal line, comparing the multi-level signal with multiple reference voltage levels, and output multiple determination values, a multiplexer recovering a bitstream from the multi-level signal based on the multiple determination values, and outputting the bitstream to the memory controller, and a control circuit aligning an edge of the first data signal with an edge of the second data signal.

### CROSS-REFERENCE TO RELATED APPLICATION

This application is based on and claims priority under 35 U.S.C. § 119 to Korean Patent Application No. 10-2024-0064805, filed on May 17, 2024, in the Korean Intellectual Property Office, the disclosure of which is incorporated by reference herein in its entirety.

### BACKGROUND

The inventive concept relates to a memory system and a method, and more particularly, a memory system and a method, which implement multi-level signaling in a low-speed NAND memory interface so as to allow a memory controller to perform high-speed communication.

Efforts to more enhance a computing system and more increase the efficiency of power have advanced interface communication and have enhanced throughput while decreasing power consumption in an ideal case without an increase in power consumption. Some systems have implemented pulse-amplitude modulation 4-level (PAM4) signaling. PAM4 signaling may be used to convert a 2-bit stream into a single multi-level signal having 4-level.

A system using semiconductor chips has widely used dynamic random access memory (DRAM) as a working memory or a main memory of the system and has used a storage device as a storage medium, so as to store data or instructions used by a host of the system and/or perform a computational operation. Storage devices include a memory controller and a non-volatile memory. The memory controller may control the non-volatile memory to write data in the non-volatile memory in response to a write request from a host, or may control the non-volatile memory to read data stored in the non-volatile memory in response to a read request from the host. As a capacity of storage devices increases, the demand for non-volatile memories having a high capacity is increasing for stable and fast processing of massive data. NAND flash memory which is a type of non-volatile memory has advantages such as a high capacity, low noise, and low power, and thus, is widely used.

PAM4 signaling may be used for high speed data transfer between NAND flash memory and the memory controller. However, in order to support PAM4 signaling, a hardware configuration of each of the memory controller and NAND flash memory may be complicated, and changing of software such as a data packet format may be involved. Therefore, there is a problem such as an increase in design costs of a memory controller and NAND flash memory for implementing PAM4 signaling.

### SUMMARY

The present disclosure provides a memory system and method for implementing multi-level signaling in a low-speed legacy NAND memory interface so as to allow a memory controller to perform high-speed communication without changing complicated hardware and software.

According to an aspect of the present disclosure, a memory system includes a first memory device including a first data pin and configured to output a first data signal through the first data pin, a second memory device including a second data pin and configured to output a second data signal through the second data pin, wherein each of the first memory device and the second memory device is a non-volatile memory device, a memory controller configured to control the first and second memory devices, a buffer chip connected between the memory controller and each of the first and second memory devices, and a first signal line connecting the buffer chip to each of the first data pin and the second data pin. The buffer chip comprises a receiver circuit configured to receive a multi-level signal from the first signal line, wherein the multi-level signal corresponds to a composite signal of the first data signal and the second data signal, compare the multi-level signal with multiple reference voltage levels, and output multiple determination values as a comparison result, a multiplexer configured to recover a bitstream including the first data signal and the second data signal from the multi-level signal based on the multiple determination values, and output the bitstream to the memory controller, and a control circuit configured to align an edge of the first data signal carried through the first signal line with an edge of the second data signal carried through the first signal line.

According to an aspect of the present disclosure, a memory system includes a memory device including a plurality of data pins having a first group of first data pins and a second group of second data pins and configured to output a plurality of data signals through the plurality of data pins, the first group of first data pins being configured to output a plurality of lower data signals of the plurality of data signals, and the second group of second data pins being configured to output a plurality of upper data signals of the plurality of data signals, a memory controller configured to control the memory device, a buffer chip connected between the memory device and the memory controller, and a plurality of first signal lines connecting the plurality of data pins to the buffer chip. Each of the plurality of first signal lines connects the buffer chip to each of a corresponding first data pin of the first group of first data pins and a corresponding second data pin of the second group of second data pins. The buffer chip comprises a receiver circuit configured to receive a plurality of multi-level signals from the plurality of first signal lines, each of the plurality of multi-level signals corresponding to a composite signal of a correspond lower data signal of the plurality of lower data signals and a corresponding upper data signal of the plurality of upper data signals, compare each of the plurality of multi-level signals with multiple reference voltage levels, and output multiple determination values for each of the plurality of multi-level signals as a comparison result, a multiplexer configured to recover each bitstream of a plurality of bitstreams from a corresponding multi-level signal of the plurality of multi-level signals using multiple determination values for the corresponding multi-level signal, each bitstream of the plurality of bitstreams including a corresponding lower data signal of the plurality of lower data signals and a corresponding upper data signal of the plurality of upper data signals, and output the plurality of bitstreams to the memory controller, and a control circuit configured to align an edge of each of the plurality of lower data signals carried through a corresponding first signal line of the plurality of first signal lines with an edge of a corresponding upper data of the plurality of upper data signals carried through the corresponding first signal line.

According to an aspect of the present disclosure A method of operating a memory system includes outputting a first data signal through a first data pin of a memory device, outputting a second data signal through a second data pin of the memory device, performing a data training operation to remove a timing skew between the first data signal and the second data signal by a memory controller controlling the memory device, thereby aligning an edge of the first data signal with an edge of the second data signal, receiving a multi-level signal through a first signal line connected to the first data pin and the second data pin by a buffer chip connected between the memory controller and the memory device, wherein the multi-level signal corresponds to a composite signal of the first data signal and the second data signal, comparing the multi-level signal with multiple reference voltage levels to output multiple determination values by the buffer chip, recovering a bitstream including the first data signal and the second data signal from the multi-level signal based on the multiple determination values by the buffer chip, and outputting the bitstream to the memory controller by the buffer chip.

### BRIEF DESCRIPTION OF THE DRAWINGS

Embodiments will be more clearly understood from the following detailed description taken in conjunction with the accompanying drawings in which:

FIGS. 1 and 2 are block diagrams illustrating a memory system according to embodiments;

FIG. 3 is a block diagram describing a memory system according to embodiments;

FIGS. 4 and 5 are diagrams describing a PAM4 signal of FIG. 3;

FIGS. 6 to 9 are diagrams describing methods of generating the PAM4 signal of FIG. 3;

FIGS. 10 and 11 are diagrams describing a receiver circuit and a multiplexer circuit of FIG. 3;

FIGS. 12A, 12B, 13A, 13B, 14A, 14B, 15A, and 15B are timing diagrams describing a timing skew between non-volatile memory devices of FIG. 3;

FIG. 16A, 16B, and 16C are diagrams describing a read performance of a memory system of FIG. 3;

FIG. 17 is a diagram describing a memory system according to embodiments;

FIG. 18 is a diagram describing a memory device according to an embodiment;

FIG. 19 is a block diagram illustrating an example where a memory system according to embodiments is applied to a solid state drive (SSD) system; and

FIG. 20 is a block diagram of a system for describing an electronic device including a memory system according to embodiments.

### DETAILED DESCRIPTION OF THE EMBODIMENTS

Multi-level signaling described herein may be used as a means which increases a bandwidth needed for transferring data at an assigned bit rate. In a simple binary method, two voltage levels may be used to represent 1 and 0 generally, and in this case, a symbol rate may be equal to a bit rate. On the other hand, by using m number of symbols for expressing data in multi-level signaling, each symbol may represent more data than 1 bit. As a result, a symbol rate may be less than a bit rate, and thus, a bandwidth may increase. In other words, multi-level signaling may be used for increasing a data transfer rate without an increase in data transfer frequency. An example of multi-level signaling may include pulse amplitude modulation (PAM), and in PAM, a multi-level signal may represent multi-bit data. In PAM, the multi-level signal may have the number of pulse amplitudes equal to 2 raised to the power of 2. For example, there may be 22 possible pulse amplitudes in 4-level PAM (i.e., PAM4), and there may be 23 possible pulse amplitudes in 8-level PAM (i.e., PAM8). However, the inventive concept is not limited thereto and may be applied to PAM(K) where there are arbitrary K (where K may be a natural number of 3 or more) number of possible pulse amplitudes.

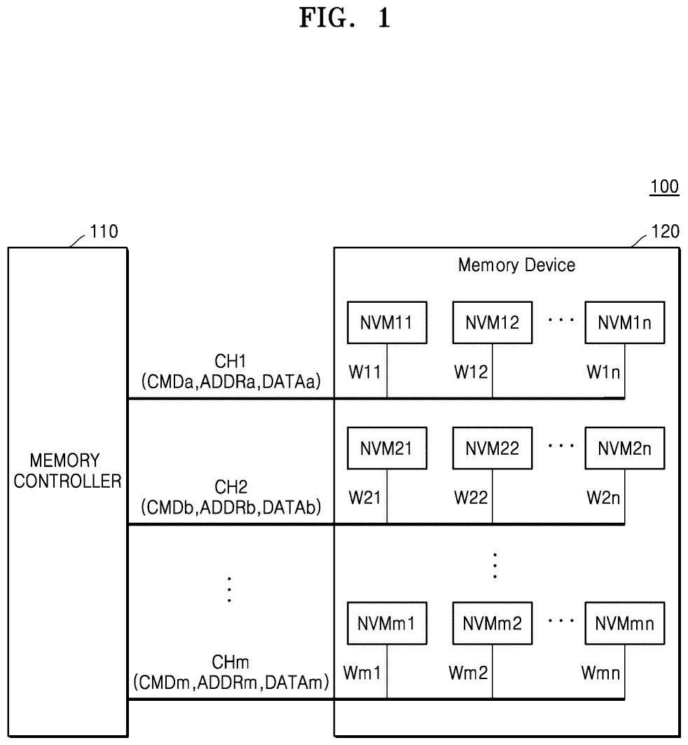

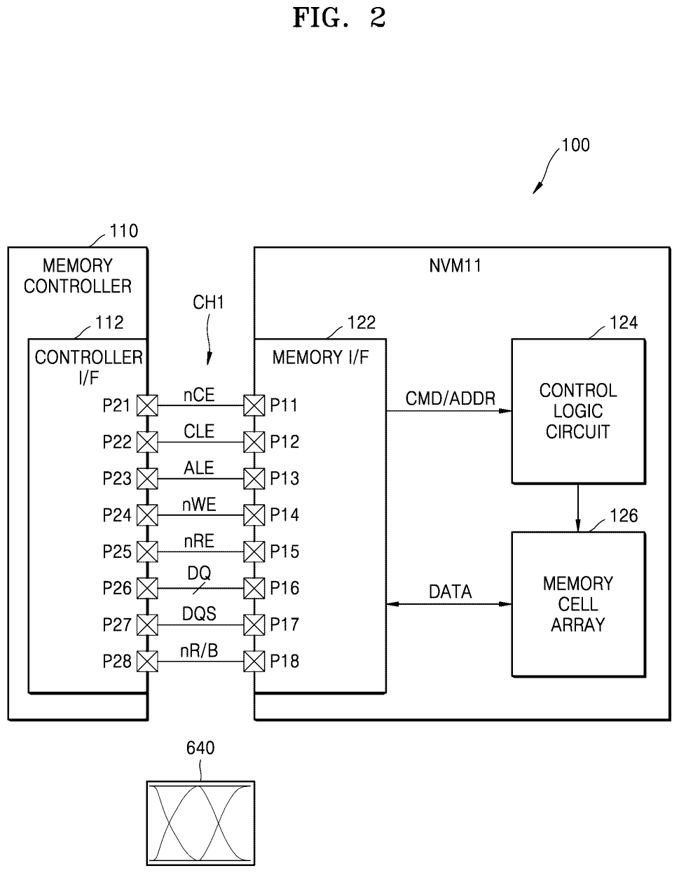

FIGS. 1 and 2 are block diagrams illustrating a memory system 100 according to embodiments. The memory system 100 of FIG. 1 may be included in an embedded universal flash storage (UFS) device, an embedded multi-media card (eMMC), a solid state drive (SSD), or an embedded SSD (eSSD), which includes a non-volatile memory device(s). The memory system 100 may be included in, for example, electronic devices such as personal computers (PCs), laptop computers, mobile phones, smartphones, tablet PCs, personal digital assistants (PDAs), enterprise digital assistants (EDA), digital still cameras, digital video cameras, audio devices, portable multimedia players (PMPs), personal navigation devices (or portable navigation devices) (PNDs), MP3 players, handheld game consoles, and e-books. Also, the memory system 100 may be included in, for example, various types of electronic devices such as wearable devices including wristwatches or head-mounted displays.

Referring to FIG. 1, the memory system 100 may include a memory controller 110 and a memory device 120. The memory system 100 may support a plurality of channels CH1, CH2, and CHm, and the memory controller 110 may be connected to the memory device 120 through the plurality of channels CH1, CH2, and CHm.

The memory device 120 may include a plurality of non-volatile memory devices NVM11 to NVMmn. Each of the non-volatile memory devices NVM11 to NVMmn may be connected to one of the plurality of channels CH1, CH2, and CHm through a corresponding way. For example, the non-volatile memory devices NVM11, NVM12, and NVM1n may be connected to a first channel CH1 through ways W11, W12, and W1n, the non-volatile memory devices NVM21, NVM22, and NVM2n may be connected to a second channel CH2 through ways W21, W22, and W2n, and the non-volatile memory devices NVMm1, NVMm2, and NVMmn may be connected to an m^{th} channel CHm through ways Wm1, W2m, and Wmn.

In some embodiments, the non-volatile memory devices NVM11, NVM12, and NVM1n may perform operations such as a write operation, a read operation, and an erase operation on data DATA in response to signals received from the memory controller 110. The non-volatile memory devices NVM11, NVM12, and NVM1n may each include a memory cell array 126 (see FIG. 2) including memory cells arranged in rows (referred to as word lines) and columns (referred to as bit lines). Each of the memory cells may store 1-bit (single-bit) data or M-bit (multi-bit) data (where M may be a natural number of 2 or more). Each memory cell may be implemented as a memory cell, including a charge storage layer such as a charge trapping layer and a floating gate, or a memory cell including a variable resistor. In the following embodiments, an example where the non-volatile memory devices NVM11, NVM12, and NVM1n store single-bit data will be described.

In some embodiments, the memory cell array 126 of each of the non-volatile memory devices NVM11, NVM12, and NVM1n may include a planar-type NAND string having a single-layer array structure or a two-dimensional (2D) array structure. In some embodiments, the memory cell array 126 may be implemented to have a multi-layer array structure or a three-dimensional (3D) array structure. A 3D memory array may include NAND strings which are arranged in a vertical direction so that at least one memory cell is disposed on another memory cell. The at least one memory cell may include a charge trapping layer.

In some embodiments, the non-volatile memory devices NVM11 to NVMmn may be implemented as an arbitrary memory unit which may operate based on an individual command from the memory controller 110. For example, each of the non-volatile memory devices NVM11 to NVMmn may be implemented as a chip or a die. This may be merely for helping to understand, and a multi-chip package MCP where the non-volatile memory devices NVM11 to NVMmn are equipped in one package may be provided for decreasing the number of equipped parts, based on the need for the miniaturization and more lightweight of electronic devices. For convenience of description, the terms “non-volatile memory devices NVM11 to NVMmn” and the terms “NVM chips” may be used to be equal to each other.

The memory controller 110 may transfer or receive signals to or from the memory device 120 through the plurality of channels CH1, CH2, and CHm. For example, the memory controller 110 may transfer commands CMDa, CMDb, and CMDm, addresses ADDRa, ADDRb, and ADDRm, and pieces of data DATAa, DATAb, and DATAm to the memory device 120 through the channels CH1, CH2, and CHm, or may receive the data DATAa, DATAb, and DATAm from the memory device 120.

The memory controller 110 may select one non-volatile memory device from among non-volatile memory devices connected to each channel through a corresponding channel and may transfer or receive signals to or from the selected non-volatile memory device. For example, the memory controller 110 may select the non-volatile memory device NVM11 from among the non-volatile memory devices NVM11, NVM12, and NVM1n connected to the first channel CH1. The memory controller 110 may transfer the command CMDa, the address ADDRa, and the data DATAa to the selected non-volatile memory device NVM11 through the first channel CH1, or may receive the data DATAa from the selected non-volatile memory device NVM11.

The memory controller 110 may transfer or receive signals to or from the memory device 120 in parallel through different channels. For example, the memory controller 110 may transfer the command CMDb to the memory device 120 through a second channel CH2 in the middle of transferring the command CMDa to the memory device 120 through the first channel CH1. For example, the memory controller 110 may receive the data DATAb from the memory device 120 through the second channel CH2 in the middle of receiving the data DATAa from the memory device 120 through the first channel CH1.

The memory controller 110 may control an overall operation of the memory device 120. The memory controller 110 may transfer a signal to the channels CH1 to CHm to control each of the non-volatile memory devices NVM11 to NVMmn connected to the channels CH1 to CHm. For example, the memory controller 110 may transfer the command CMDa and the address ADDRa to the first channel CH1 to control one selected non-volatile memory device of the non-volatile memory devices NVM11 to NVMmn.

Each of the non-volatile memory devices NVM11 to NVMmn may operate based on control by the memory controller 110. For example, the non-volatile memory device NVM11 may program the data DATAa, based on the command CMDa, the address ADDRa, and the data DATAa each provided to the first channel CH1. For example, the non-volatile memory device NVM21 may read the data DATAb, based on the command CMDb and the address ADDRb each provided to the second channel CH2 and may transfer the read data DATAb to the memory controller 110.

In FIG. 1, it is illustrated that the memory device 120 communicates with the memory controller 110 through m number of channels and includes n number of non-volatile memory devices per channel, but the inventive concept is not limited thereto and the number of channels and the number of non-volatile memory devices connected to one channel may be variously changed.

FIG. 2 illustrates an NVM11 chip of the non-volatile memory devices NVM11, NVM12, and NVM1n communicating with the memory controller 110, based on one (for example, the first channel CH1) of the plurality of channels CH1 to CHm of FIG. 1. Descriptions of the NVM11 chip may be identically applied to the other NVM chips NVM12 and NVM1n of the first channel CH1. Also, the descriptions of the NVM11 chip may be identically applied to NVM chips NVM21, NVM22, NVM2n, NVMm1, NVMm2, and NVMmn connected to the other channels CH2 to CHm.

Referring to FIG. 2, the NVM11 chip may include first to eighth pins P11 to P18, a memory interface circuit 122, a control logic circuit 124, and a memory cell array 126. The memory interface circuit 122 may receive a chip enable signal nCE from the memory controller 110 through the first pin P11. The memory interface circuit 122 may transfer or receive signals to or from the memory controller 110 through the second to eighth pins P12 to P18, based on the chip enable signal nCE. For example, when the chip enable signal nCE has an enable state (for example, a low level), the memory interface circuit 122 may transfer or receive signals to or from the memory controller 110 through the second to eighth pins P12 to P18.

The memory interface circuit 122 may receive a command latch enable signal CLE, an address latch enable signal ALE, and a write enable signal nWE from the memory controller 110 through the second to fourth pins P12 to P14. The memory interface circuit 122 may receive a data signal DQ from the memory controller 110 through the sixth pin P16, or may transfer the data signal DQ to the memory controller 110. A command CMD, an address ADDR, and data DATA may be transferred based on the data signal DQ. For example, the data signal DQ may be transferred through a plurality of data signal lines. In this case, the sixth pin P16 may include a plurality of pins corresponding to a plurality of data signals. In some embodiments, the sixth pin P16 may include eight pins corresponding to eight data signals DQ<7:0>, or may include sixteen pins corresponding to sixteen data signals DQ<15:0>.

The memory interface circuit 122 may obtain a command CMD from the data signal DQ received in an enable period (for example, a high level state) of the command latch enable signal CLE, based on toggle timings of the write enable signal nWE. The memory interface circuit 122 may obtain an address ADDR from the data signal DQ received in an enable period (for example, a high level state) of the address latch enable signal ALE, based on the toggle timings of the write enable signal nWE.

In some embodiments, the write enable signal nWE may maintain a static state (for example, a high level or a low level) and may then toggle between a high level and a low level. For example, the write enable signal nWE may toggle in a period where the command CMD or the address ADDR is transferred. Therefore, the memory interface circuit 122 may obtain the command CMD or the address ADDR, based on the toggle timings of the write enable signal nWE.

The memory interface circuit 122 may receive a read enable signal nRE from the memory controller 110 through the fifth pin P15. The memory interface circuit 122 may receive a data strobe signal DQS from the memory controller 110 through the seventh pin P17, or may transfer the data strobe signal DQS to the memory controller 110.

In a data DATA output operation of the NVM11 chip, the memory interface circuit 122 may receive the read enable signal nRE toggling through the fifth pin P15 before outputting the data DATA. The memory interface circuit 122 may generate the data strobe signal DQS toggling, based on toggling of the read enable signal nRE. For example, the memory interface circuit 122 may generate the data strobe signal DQS which starts to toggle after predetermined delay (for example, tDQSRE), with respect to a toggling start time of the read enable signal nRE. The memory interface circuit 122 may transfer the data signal DQ including the data DATA, based on a toggle timing of the data strobe signal DQS. Accordingly, the data DATA may be aligned at the toggle timing of the data strobe signal DQS and may be transferred to the memory controller 110. For example, the data DATA may be transferred to the memory controller 110 in synchronization with the toggle timing of the data strobe signal DQS.

In a data DATA input operation of the NVM11 chip, when the data signal DQ including the data DATA is received from the memory controller 110, the memory interface circuit 122 may receive, from the memory controller 110, the data strobe signal DQS toggling along with the data DATA. The memory interface circuit 122 may obtain the data DATA from the data signal DQ, based on the toggle timing of the data strobe signal DQS. For example, the memory interface circuit 122 may sample the data signal DQ at a rising edge and a falling edge of the data strobe signal DQS to obtain the data DATA.

The memory interface circuit 122 may transfer a ready/busy output signal nR/B to the memory controller 110 through the eighth pin P18. The memory interface circuit 122 may transfer state information about the NVM11 chip to the memory controller 110, based on the ready/busy output signal nR/B. When the NVM11 chip is in a busy state (i.e., when internal operations of the NVM11 chip are being performed), the memory interface circuit 122 may transfer the ready/busy output signal nR/B representing the busy state of the NVM11 chip to the memory controller 110. When the NVM11 chip is in a ready state (i.e., when the internal operations of the NVM11 chip are not performed or are completed), the memory interface circuit 122 may transfer the ready/busy output signal nR/B representing the ready state of the NVM11 chip to the memory controller 110. For example, while the NVM11 chip is reading the data DATA from the memory cell array 126 in response to a page read command, the memory interface circuit 122 may transfer the ready/busy output signal nR/B representing the busy state (for example, a low level) to the memory controller 110. For example, while the NVM11 chip is programming the data DATA in the memory cell array 126 in response to a program command, the memory interface circuit 122 may transfer the ready/busy output signal nR/B representing the busy state of the NVM11 chip to the memory controller 110.

The control logic circuit 124 may control various operations of the NVM11 chip. The control logic circuit 124 may receive a command/address CMD/ADDR from the memory interface circuit 122. The control logic circuit 124 may generate control signals for controlling the other elements of the NVM11 chip, based on the received command/address CMD/ADDR. For example, the control logic circuit 124 may program the data DATA in the memory cell array 126, or may generate various control signals for reading the data DATA from the memory cell array 126.

The memory cell array 126 may store the data DATA obtained from the memory interface circuit 122, based on control by the control logic circuit 124. The memory cell array 126 may output the stored data DATA to the memory interface circuit 122, based on control by the control logic circuit 124.

The memory cell array 126 may include a plurality of memory cells. For example, the plurality of memory cells may be flash memory cells. However, the inventive concept is not limited thereto, and the memory cells may be resistive random access memory (RRAM) cells, ferroelectric random access memory (FRAM) cells, phase change random access memory (PRAM) cells, thyristor random access memory (TRAM) cells, or magnetic random access memory (MRAM) cells. Hereinafter, an embodiment where memory cells are NAND flash memory cells will be mainly described.

The memory controller 110 may include first to eighth pins P21 to P28 and a controller interface circuit 112. The first to eighth pins P21 to P28 may respectively correspond to the first to eighth pins P11 to P18 of the NVM11 chip.

The controller interface circuit 112 may send the chip enable signal nCE to the NVM11 chip through the first pin P21. The controller interface circuit 112 may transfer or receive signals to or from the memory device 120, selected based on the chip enable signal nCE, through the second to eighth pins P22 to P28.

The memory interface circuit 122 may transfer the command latch enable signal CLE, the address latch enable signal ALE, and the write enable signal nWE to the NVM11 chip through the second to fourth pins P22 to P24. The controller interface circuit 112 may transfer the data signal DQ to the NVM11 chip through the sixth pin P26, or may receive the data signal DQ from the NVM11 chip.

The controller interface circuit 112 may transfer, to the NVM11 chip, the data signal DQ including the command CMD or the address ADDR along with the write enable signal nWE toggling. The controller interface circuit 112 may transfer the command latch enable signal CLE having an enable state to transfer the data signal DQ including the command CMD to the NVM11 chip and may transfer the address latch enable signal ALE having an enable state to transfer the data signal DQ including the address ADDR to the NVM11 chip.

The controller interface circuit 112 may send the read enable signal nRE to the NVM11 chip through the fifth pin P25. The controller interface circuit 112 may receive the data strobe signal DQS from the NVM11 chip through the seventh pin P27, or may transfer the data strobe signal DQS to the NVM11 chip.

In a data DATA output operation of the NVM11 chip, the controller interface circuit 112 may generate the read enable signal nRE and may transfer the read enable signal nRE to the NVM11 chip. For example, the controller interface circuit 112 may generate the read enable signal nRE changed from a static state (for example, a high level or a low level) to a toggle state before the data DATA is output. Accordingly, the NVM11 chip may generate the data strobe signal DQS toggling, based on the read enable signal nRE. The controller interface circuit 112 may receive, from the NVM11 chip, the data signal DQ including the data DATA along with the data strobe signal DQS toggling. The controller interface circuit 112 may obtain the data DATA from the data signal DQ, based on the toggle timing of the data strobe signal DQS.

In a data DATA input operation of the NVM11 chip, the controller interface circuit 112 may generate the data strobe signal DQS. For example, the controller interface circuit 112 may generate the data strobe signal DQS changed from the static state (for example, a high level or a low level) to the toggle state before transferring the data DATA. The memory interface circuit 122 may transfer the data signal DQ including the data DATA to the NVM11 chip, based on the toggle timing of the data strobe signal DQS.

The controller interface circuit 112 may receive the ready/busy output signal nR/B from the NVM11 chip through the eighth pin P28. The controller interface circuit 112 may determine state information about the NVM11 chip, based on the ready/busy output signal nR/B.

In FIG. 2, a data signal DQ line of the memory system 100 may carry a signal 640 which is referred to as a non-return-to-zero (NRZ) signal. The signal 640 may include binary encoding which represents one bit (for example, 1 or 0) per symbol period. As the amount of data processed in an electronic device increases, the amount of processed data may increase beyond a communication speed or a data bandwidth of an interface connected to storage devices (for example, SSD), causing a data bottleneck phenomenon. Because such phenomenon reduces the performance of electronic devices, various performance enhancement methods are being developed.

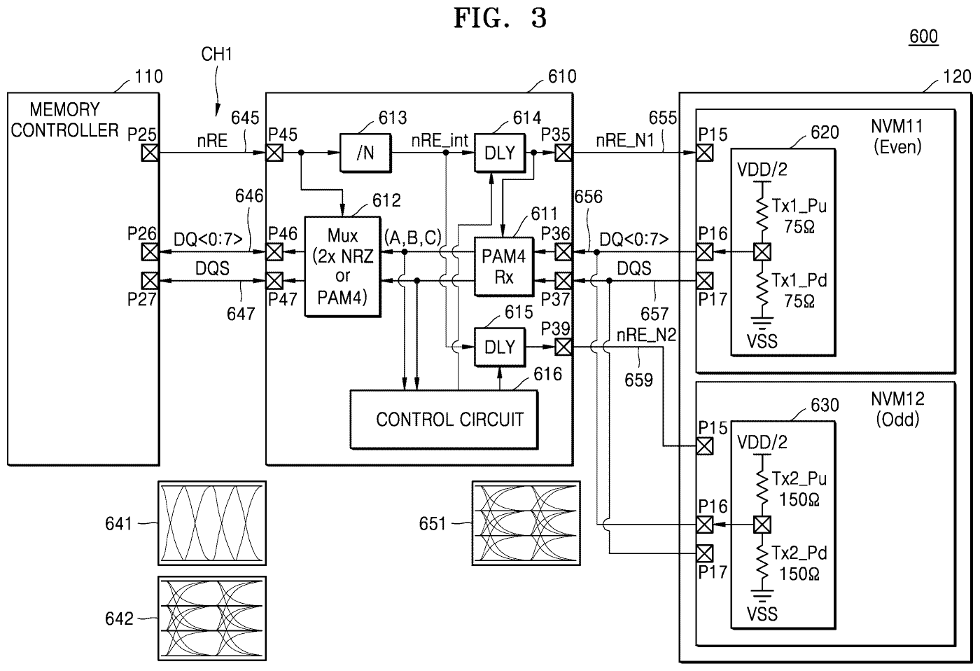

The memory system 100 may design a number of data signal DQ pins and channels for enhancing the read performance of the memory system 100. A termination circuit for receiving data may be connected to each of a number of data signal DQ pins (for example, may be sometimes coupled to at least a portion of output drivers 620 and 630 (see FIG. 3)). The termination circuit may provide a termination resistance value for providing impedance matching on the data signal DQ line. When an output impedance of a transmitting side does not match an impedance of a receiving side, signal reflection may occur in the receiving side and a reflected signal may not be normally transferred, and due to this, a voltage level of the receiving side may be shifted, causing a problem where signal transfer is not normally performed. Signal reflection may be prevented by impedance matching of the data signal DQ line, and thus, the signal integrity of a transferred/received data signal DQ may be enhanced. However, a termination operation on the more data signal DQ lines may cause a problem where large power consumption occurs. Also, the memory controller 110 connected to the more data signal DQ lines may cause an increase in chip size. In the following description, multi-level signaling for increasing a sequential/random read direct memory access (DMA) from the memory device 120 to the memory controller 110 without changing complicated hardware and software in a low-speed legacy NAND memory interface will be described.

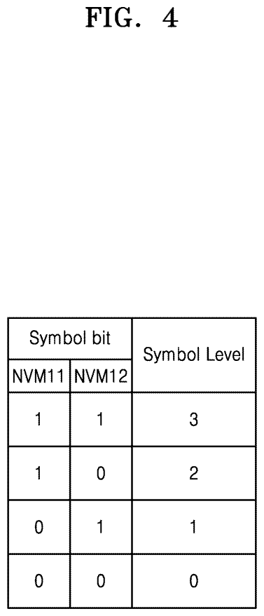

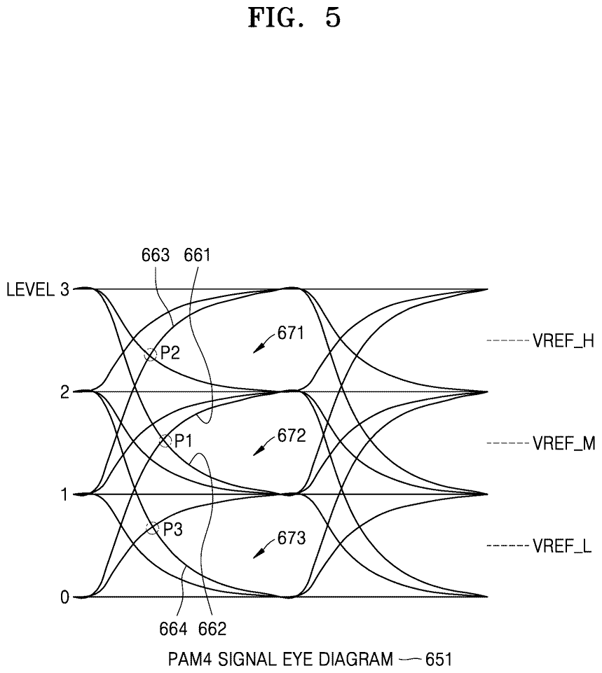

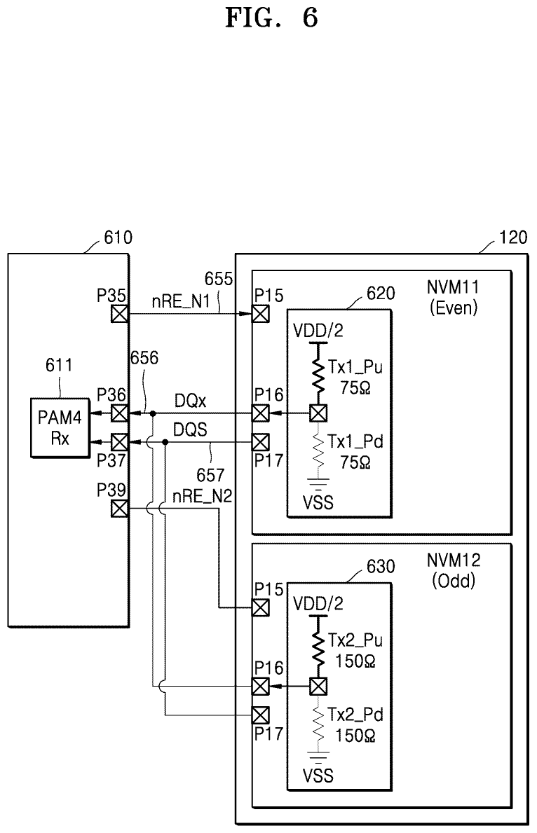

FIG. 3 is a block diagram describing a memory system 600 according to embodiments. FIGS. 4 and 5 are diagrams describing a PAM4 signal 651 of FIG. 3, and FIGS. 6 to 9 are diagrams describing methods of generating the PAM4 signal 651 of FIG. 3.

Referring to FIG. 3, comparing with the memory system 100 of FIG. 1, the memory system 600 may have a difference in that a buffer chip 610 is provided between a memory controller 110 and a memory device 120. Also, there may be a difference in that the driving strength of an output driver 620 of a first non-volatile memory device NVM11 connected to a first channel CH1 and the driving strength of an output driver 630 of a second non-volatile memory device NVM12 connected to the first channel CH1 are differently set. For convenience of description, the memory system 600 may implement multi-level signaling in terms of P15, P16, P17, P25, P26 and P27 pins, to which a read enable signal nRE, a data signal DQ, and a data strobe signal DQS are transferred, among the first to eighth pins P11 to P18 of the memory interface circuit 122 and the first to eighth pins P21 to P28 of the controller interface circuit 112 each described above with reference to FIG. 2. Hereinafter, descriptions of the memory system 600 which are the same as or similar to the descriptions of FIG. 2 are omitted.

In the memory system 600, an NVM11 chip and an NVM12 chip of the memory device 120 may communicate with the memory controller 110 through the first channel CH1 by using a buffer chip 610. The NVM11 chip may include the P15, P16, and P17 pins to which a first read enable signal nRE_N1, eight data signals DQ<7:0>, and the data strobe signal DQS are transferred, and the P16 pin may be configured with eight pins respectively corresponding to the eight data signals DQ<7:0>. The NVM12 chip may include the P15, P16, and P17 pins to which a second read enable signal nRE_N2, eight data signals DQ<7:0>, and the data strobe signal DQS are transferred, and the P16 pin may be configured with eight pins respectively corresponding to the eight data signals DQ<7:0>.

In some embodiments, each of the NVM11 chip and the NVM12 chip may be configured with a various number of NVM chips. For example, the NVM chips may be 2n (where n may be 0, 1, 2, and 3) number. The memory controller 110 may divide a plurality of NVM chips into a logical and/or physical group, in terms of power control and address designation/memory access. For example, the NVM11 chips may be configured with even chips, and the NVM12 chips may be configured with odd chips.

The NVM11 chip may include the control logic circuit 124 and the memory cell array 126 each described above with reference to FIG. 2 and may include an output driver 620 connected to the P16 pin. The output driver 620 may include a first pull-up resistor Tx1_Pu and a first pull-down resistor Tx1_Pd each connected between a first voltage level VDD/2 and a second voltage level VSS, and a connection node between the first pull-up resistor Tx1_Pu and the first pull-down resistor Tx1_Pd may be connected to the P16 pin. The first voltage level VDD/2 may be set to a voltage level which corresponds to half of a source voltage level VDD of the memory device 120, and the second voltage level VSS may be set to a ground voltage level of the memory device 120. In FIG. 3, it is illustrated that the output driver 620 is modeled with the first pull-up resistor Tx1_Pu and the first pull-down resistor Tx1_Pd, but this may be understood for providing a swing width and/or driving strength of data output from the output driver 620 and providing a termination resistor for receiving data through the P16 pin. For example, the first pull-up resistor Tx1_Pu may be set to have a resistance value of about 75Ω, and the first pull-down resistor Tx1_Pd may be set to have a resistance value of about 75Ω. In other words, FIG. 3 shows an equivalent circuit of the output driver 620, which is modeled with the first pull-up register Tx1_Pu and the first pull-down resistor Tx1_Pd. In some embodiments, the first pull-up resistor Tx1_Pu may correspond to a turn-on pull-up transistor having a resistance value of about 75Ω, and the first pull-down resistor Tx1_Pd may correspond to a turn-on pull-down transistor having a resistance value of about 75Ω.

The NVM12 chip may include a control logic circuit 124, a memory cell array 126, and an output driver 630 connected to the P16 pin. The output driver 630 may include a second pull-up resistor Tx2_Pu and a second pull-down resistor Tx2_Pd each connected between the first voltage level VDD/2 and the second voltage level VSS, and a connection node between the second pull-up resistor Tx2_Pu and the second pull-down resistor Tx2_Pd may be connected to the P16 pin. For example, the second pull-up resistor Tx2_Pu may be set to have a resistance value of about 150Ω, and the second pull-down resistor Tx2_Pd may be set to have a resistance value of about 150Ω. In other words, FIG. 3 shows an equivalent circuit of the output driver 620, which is modeled with the second pull-up register Tx2_Pu and the second pull-down resistor Tx1_Pd. In some embodiments, the second pull-up resistor Tx2_Pu may correspond to a turn-on pull-up transistor having a resistance value of about 150Ω, and the second pull-down resistor Tx2_Pd may correspond to a turn-on pull-down transistor having a resistance value of about 150Ω.

In some embodiments, the first pull-up resistor Tx1_Pu and the first pull-down resistor Tx1_Pd of the NVM11 chip may be set to have a resistance value of about 150Ω, and the second pull-up resistor Tx2_Pu and the second pull-down resistor Tx2_Pd of the NVM12 chip may be set to have a resistance value of about 75Ω. This may be merely an embodiment for helping understanding and may denote that the first pull-up resistor Tx1_Pu and the first pull-down resistor Tx1_Pd of the NVM11 chip and the second pull-up resistor Tx2_Pu and the second pull-down resistor Tx2_Pd of the NVM12 chip have different resistance values.

The buffer chip 610 may include a receiver circuit 611, a multiplexer circuit 612, a divider circuit 613, a first delay circuit 614, a second delay circuit 615, and a control circuit 616. A configuration of the buffer chip 610 illustrated in FIG. 3 may not represent or imply a limitation of the inventive concept. This may be merely an embodiment for helping understanding and may be a non-limiting embodiment for the purpose of describing PAM4 signaling on a data signal DQ. According to embodiments, the buffer chip 610 may include a logical layer and a physical or electrical layer, which are provided for signals, a frequency, a timing, driving, a detailed operation parameter, and functionality each needed for efficient communication between the memory controller 110 and the memory device 120.

The buffer chip 610 may include P35, P36, P37, and P39 pins connected to the memory device 120 and may include P45, P46, and P47 pins connected to the memory controller 110. The buffer chip 610 may receive a read enable signal nRE output from a P25 pin of the memory controller 110 through the P45 pin. The read enable signal nRE may be added to a signal line 645 between the P25 pin and the P45 pin and may be a read enable signal of the memory device 120.

The buffer chip 610 may receive data signals DQ<7:0> output from a P26 pin of the memory controller 110 through the P46 pin, or may transfer the data signals DQ<7:0> of the memory device 120 to the P26 pin of the memory controller 110. The data signals DQ<7:0> may be added to the signal line 646 between the P26 pin and the P46 pin. The multiplexer circuit 612 may provide data signals DQ<7:0> having an NRZ signal 641 waveform to the signal line 646. According to an embodiment, the multiplexer circuit 612 may provide data signals DQ<7:0> having a PAM4 signal 642 waveform to the signal line 646. The PAM2 signal 642 may be the same as a PAM4 signal 651 received by the receiver circuit 611. The NRZ signal 641 may have a double data rate with respect to the PAM4 signals 642 and 651.

The buffer chip 610 may receive a data strobe signal DQS output from a P27 pin of the memory controller 110 through the P47 pin, or may transfer the data strobe signal DQS output from the memory device 120 to the P27 pin of the memory controller 110. The data strobe signal DQS may be added to a signal line 647 between the P27 pin and the P47 pin.

The buffer chip 610 may transfer a first read enable signal nRE_N1 to a P15 pin of the NVM11 chip of the memory device 120 through the P35 pin. The first read enable signal nRE_N1 may be added to a signal line 655 between the P35 pin and the P15 pin of the NVM11 chip and may be a read enable signal of the NVM11 chip. The buffer chip 610 may transfer a second read enable signal nRE_N2 to a P17 pin of the NVM12 chip of the memory device 120 through the P39 pin. The second read enable signal nRE_N2 may be added to a signal line 659 between the P39 pin and the P15 pin of the NVM12 chip and may be a read enable signal of the NVM12 chip.

The buffer chip 610 may receive, through the P36 pin, data signals DQ<7:0> output from the P16 pin of the NVM11 chip and data signals DQ<7:0> output from the P16 pin of the NVM12 chip. The data signals DQ<7:0> of the NVM11 chip and the data signals DQ<7:0> of the NVM12 chip may be coupled to each other and may be added to a signal line 656 between the P36 pin, the P16 pin of the NVM11 chip, and the P16 pin of the NVM12 chip. The PAM4 signal 651, having a data eye diagram where swings of signals transferred at several multi-levels (for example, a 4-symbol level) are seen to overlap, may be added to the signal line 656, and the PAM4 signal 651 may have a half data rate compared to the NRZ signal 641.

The buffer chip 610 may receive, through the P37 pin, a data strobe signal DQS output from the P17 pin of the NVM11 chip and a data strobe signal DQS output from the P17 pin of the NVM12 chip. The data strobe signal DQS of the NVM11 chip and the data strobe signal DQS of the NVM12 chip may be coupled to each other and may be added to a signal line 657 between the P37 pin, the P17 pin of the NVM11 chip, and the P17 pin of the NVM12 chip.

FIG. 4 describes a 2-bit PAM4 symbol level added to the signal line 656, and this is a non-limiting embodiment for the purpose of description and describes mapping between PAM4 symbols and symbol bits. Referring to FIG. 4, each of the PAM4 symbols may consist of 2 bits and may be represented by 4 symbol levels. A 2-bit PAM4 symbol may be transferred at four symbol levels, represented as a level 0, 1, 2, or 3, to the signal line 656. Each of four symbol levels may have one of four voltage levels. In an embodiment, a PAM4 symbol of the level 3 may be represented by a symbol bit 11 and may be set to have a highest voltage level (for example, 3/6*VDD). A PAM4 symbol of the level 2 may be represented by a symbol bit 10 and may be set to have a voltage level (for example, 2/6*VDD) which is lower than the PAM4 symbol of the level 3. A PAM4 symbol of the level 1 may be represented by a symbol bit 01 and may be set to have a voltage level (for example, 1/6*VDD) which is lower than the PAM4 symbol of the level 2. A PAM4 symbol of the level 0 may be represented by a symbol bit 00 and may be set to have a lowest voltage level (for example, 0 V).

FIG. 5 describes an eye diagram of the PAM4 signal 651 of the signal line 656. The PAM4 eye diagram is plotted as a voltage of a signal line with respect to a time in the signal line 656. The ordinate axis represents a voltage, and the abscissa axis represents a time interval equal to 2 symbol periods, but the drawing is not illustrated at a constant rate. Referring to FIG. 5, in the PAM4 eye diagram, several cross points (for example, small circle plots) may be shown by shifts to several symbol levels. A cross point P1 of a shift waveform 661 from a symbol level 0 to a symbol level 2 and a shift waveform 662 from a symbol level 3 to a symbol level 1 among the several cross points may be shown. Also, across point P2 of a shift waveform 663 from a symbol level 1 to a symbol level 3 and a cross point P3 of a shift waveform 664 from the symbol level 2 to the symbol level 0 may be shown. Based on the shift waveforms 661, 662, 663, and 664, eye openings 671, 672, and 673 may appear. Hereinafter, methods of generating the PAM4 signal 651 in the signal line 656 will be described.

FIGS. 6 to 9 are diagrams describing methods of generating the PAM4 signal 651 in the signal line 656 of FIG. 3. For convenience of description, the PAM4 signal 651 of the signal line 656 carrying one data signal DQx of data signals DQ<7:0> may be described. To simplify a circuit connection relationship, elements having a disable state may be lightly shown because of not being connected.

Referring to FIG. 6, in a memory device 120, an NVM11 chip may output a data signal DQx having a logic high level to a P16 pin, and an NVM12 chip may output a data signal DQx having a logic high level to a P16 pin. The NVM11 chip may transfer a first voltage level VDD/2 to the signal line 656 through a first pull-up resistor Tx1_Pu, and the NVM12 chip may transfer the first voltage level VDD/2 to the signal line 656 through a second pull-up resistor Tx2_Pu. Accordingly, the signal line 656 may output the first voltage level VDD/2. This may denote that a PAM4 signal of a level 3 which is plotted as the symbol bit 11 described above with reference to FIG. 4 and has a 3/6*VDD voltage level is generated in the signal line 656.

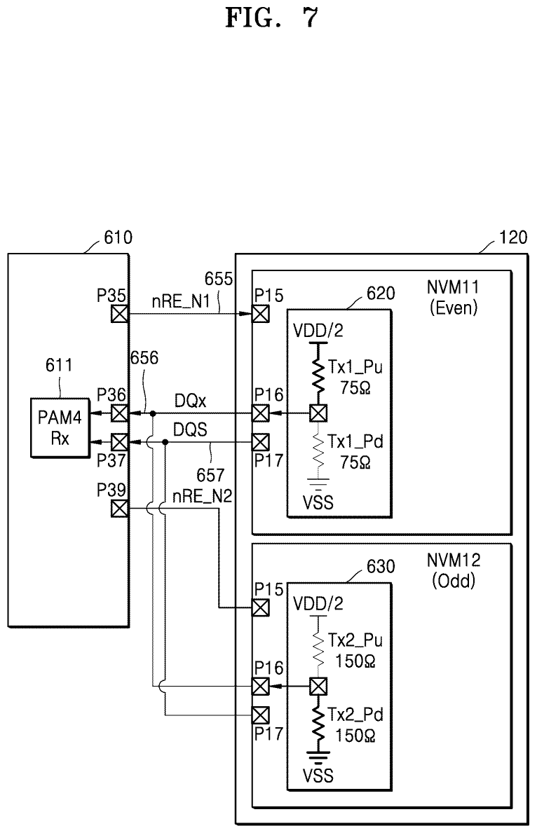

Referring to FIG. 7, in a memory device 120, an NVM11 chip may output a data signal DQx having a logic high level to a P16 pin, and an NVM12 chip may output a data signal DQx having a logic low level to a P16 pin. The NVM11 chip may transfer a first voltage level VDD/2 to a signal line 656 through a first pull-up resistor Tx1_Pu, and the NVM12 chip may transfer a second voltage level VSS to the signal line 656 through a second pull-down resistor Tx2_Pd. Accordingly, the signal line 656 may be connected between the first pull-up resistor Tx1_Pu connected to a first voltage level VDD/2 line and the second pull-down resistor Tx2_Pd connected to a second voltage level VSS line. The signal line 656 may output a third voltage level VDD/3, based on a resistance value of about 75Ω of the first pull-up resistor Tx1_Pu and a resistance value of about 150Ω of the second pull-down resistor Tx2_Pd. This may denote that a PAM4 signal of a level 2 which is plotted as the symbol bit 10 described above with reference to FIG. 4 and has a 2/6*VDD voltage level is generated in the signal line 656.

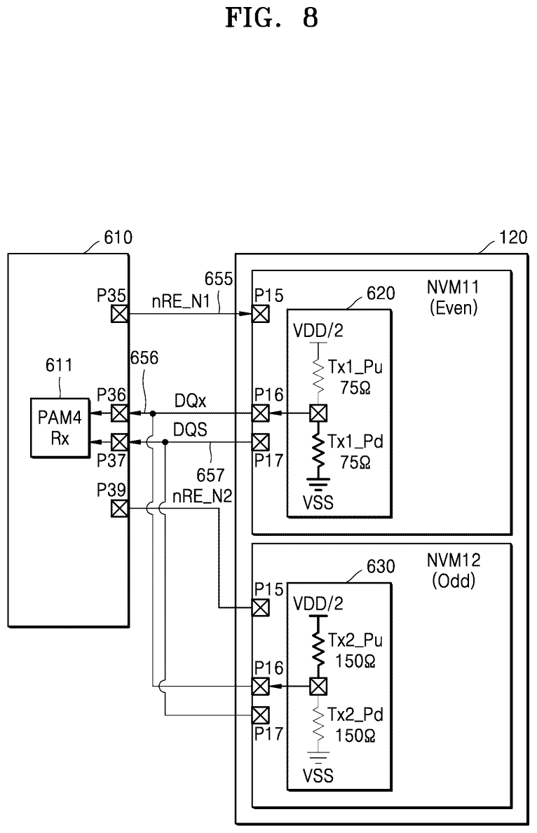

Referring to FIG. 8, in a memory device 120, an NVM11 chip may output a data signal DQx having a logic low level to a P16 pin, and an NVM12 chip may output a data signal DQx having a logic high level to a P16 pin. The NVM11 chip may transfer a second voltage level VSS to the signal line 656 through a first pull-down resistor Tx1_Pd, and the NVM12 chip may transfer the first voltage level VDD/2 to the signal line 656 through a second pull-up resistor Tx2_Pu. Accordingly, the signal line 656 may be connected between the second pull-up resistor Tx2_Pu connected to the first voltage level VDD/2 line and the first pull-down resistor Tx1_Pd connected to a second voltage level VSS line. The signal line 656 may output a fourth voltage level VDD/6, based on a resistance value of about 150Ω of the second pull-up resistor Tx2_Pu and a resistance value of about 75Ω of the first pull-down resistor Tx1_Pd. This may denote that a PAM4 signal of a level 1 which is plotted as the symbol bit 01 described above with reference to FIG. 4 and has a 1/6*VDD voltage level is generated in the signal line 656.

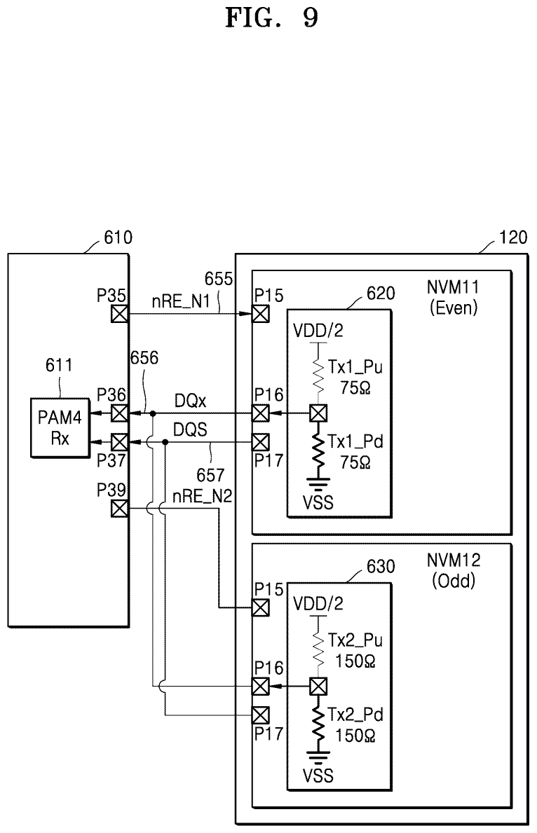

Referring to FIG. 9, in a memory device 120, an NVM11 chip may output a data signal DQx having a logic low level to a P16 pin, and an NVM12 chip may output a data signal DQx having a logic low level to a P16 pin. The NVM11 chip may transfer a second voltage level VSS to the signal line 656 through a first pull-down resistor Tx1_Pd, and the NVM12 chip may transfer the second voltage level VSS to the signal line 656 through a second pull-down resistor Tx2_Pd. Accordingly, the signal line 656 may output the second voltage level VSS. This may denote that a PAM4 signal of a level 3 which is plotted as the symbol bit 00 described above with reference to FIG. 4 and has a a voltage level of 0 V is generated in the signal line 656.

In FIGS. 6 to 9, a significant timing in operations of generating the PAM4 signal 651 of the signal line 656 may be that an edge of a data signal DQx of the NVM11 chip output based on the first read enable signal nRE_N1 of the NVM11 chip is aligned with an edge of a data signal DQx of the NVM12 chip output based on the second read enable signal nRE_N2 of the NVM12 chip. The buffer chip 610 may adjust a timing of each of the first read enable signal nRE_N1 and the second read enable signal nRE_N2 so that the edge of the data signal DQx of the NVM11 chip is aligned with the edge of the data signal DQx of the NVM12 chip. Subsequently, the buffer chip 610 may receive the PAM4 signal 651 of the signal line 656 and may determine a symbol level of the PAM4 signal 651 to generate a 2-bitstream signal corresponding to the PAM4 symbol level.

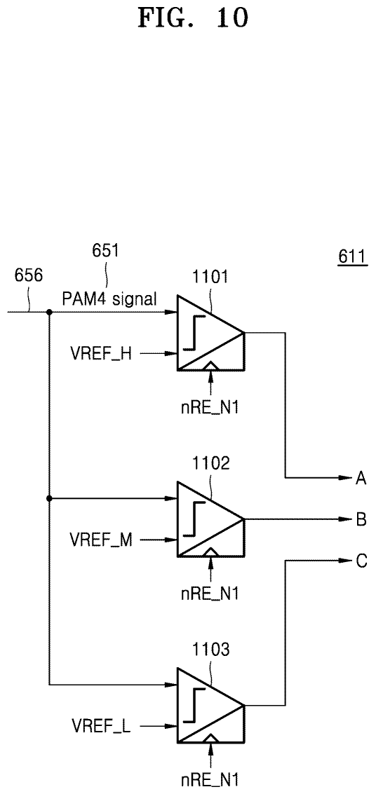

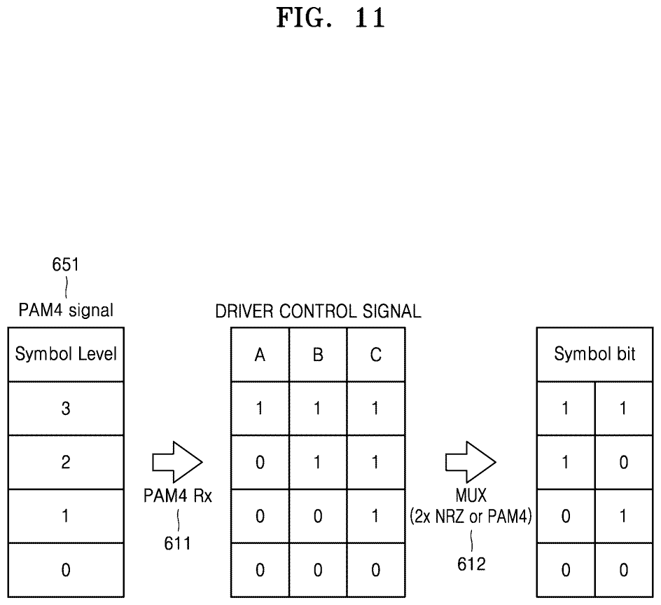

FIGS. 10 and 11 are diagrams describing the receiver circuit 611 and the multiplexer circuit 612 of FIG. 3.

Referring to FIG. 10, a receiver circuit 611 may include a plurality of sampler circuits (i.e., comparator circuits), and for example, may include a first sampler circuit 1101, a second sampler circuit 1102, and a third sampler circuit 1103. The first sampler circuit 1101 may compare a PAM4 signal 651 of a signal line 656 with a first reference voltage level VREF_H to output a first determination value A, in response to a first read enable signal nRE_N1. The first reference voltage level VREF_H, as illustrated in FIG. 5, may be a voltage level between a symbol level 2 and a symbol level 3.

The second sampler circuit 1102 may compare the PAM4 signal 651 of the signal line 656 with a second reference voltage level VREF_M to output a second determination value B, in response to the first read enable signal nRE_N1. The second reference voltage level VREF_M, as illustrated in FIG. 5, may be a voltage level between a symbol level 1 and the symbol level 2.

The third sampler circuit 1103 may compare the PAM4 signal 651 of the signal line 656 with a third reference voltage level VREF_L to output a third determination value C, in response to the first read enable signal nRE_N1. The third reference voltage level VREF_L, as illustrated in FIG. 5, may be a voltage level between a symbol level 0 and the symbol level 1.

As illustrated in FIG. 11, when the PAM4 signal 651 is the symbol level 3, the receiver circuit 651 may output all of the first determination value A, the second determination value B, and the third determination value C as ‘1’. When the PAM4 signal 651 is the symbol level 2, the receiver circuit 651 may output the first determination value A as ‘O’ and may output the second determination value B and the third determination value C as ‘1’. When the PAM4 signal 651 is the symbol level 1, the receiver circuit 651 may output the first determination value A and the second determination value B as ‘0’ and may output the third determination value C as ‘1’. When the PAM4 signal 651 is the symbol level 0, the receiver circuit 651 may output all of the first determination value A, the second determination value B, and the third determination value C as ‘0’.

Referring to FIGS. 3 and 11, the first determination value A, the second determination value B, and the third determination value C of the receiver circuit 611 may be provided to the multiplexer circuit 612 and the control circuit 616. The multiplexer circuit 612 may map multiple determination values A, B, and C of the receiver circuit 611 to a 2-bitstream signal. For example, when the multiple determination values A, B, and C are “111”, the multiple determination values A, B, and C may be mapped to a 2-bitstream signal representing a bitstream of “11”, and when the multiple determination values A, B, and C are “011”, the multiple determination values A, B, and C may be mapped to a 2-bitstream signal representing a bitstream of “10”. Also, when the multiple determination values A, B, and C are “001”, the multiple determination values A, B, and C may be mapped to a 2-bitstream signal representing a bitstream of “01”, and when the multiple determination values A, B, and C are “000”, the multiple determination values A, B, and C may be mapped to a 2-bitstream signal representing a bitstream of “00”. In the multiplexer circuit 612, a 2-bitstream signal mapped to the multiple determination values A, B, and C of the receiver circuit 611 may be obtained by recovering the data signal DQx of the NVM11 chip and the data signal DQx of the NVM12 chip. The multiplexer circuit 612 may transfer the data signal DQx of the NVM11 chip and the data signal DQx of the NVM12 chip as a recovered 2-bitstream signal, to the memory controller 110. The 2-bitstream signal output from the multiplexer circuit 612 may be transferred as the data signals DQ<7:0> of the memory device 120 to the P26 pin of the memory controller 110 through the P46 pin of the buffer chip 610.

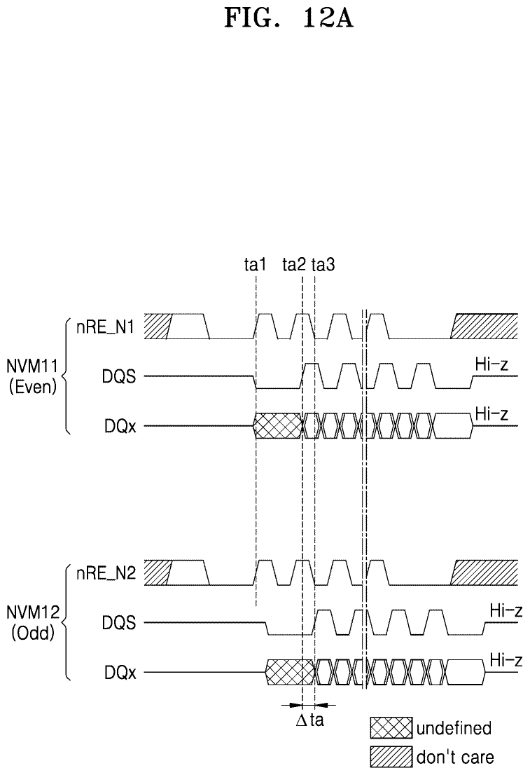

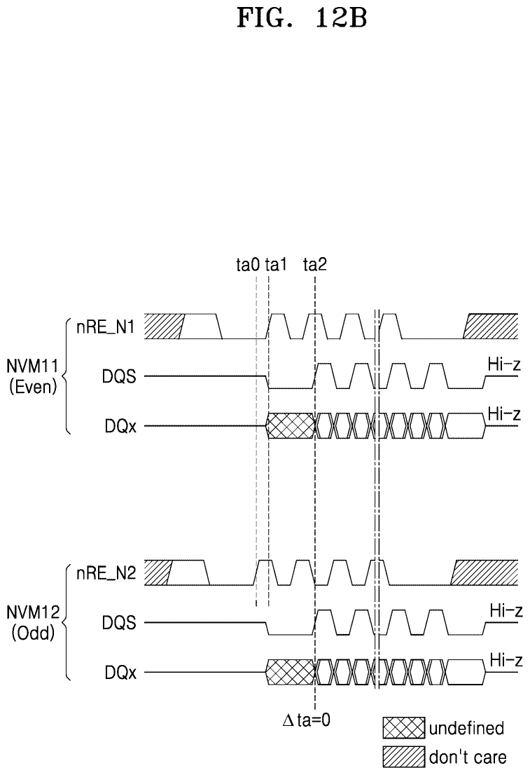

Furthermore, before the receiver circuit 611 determines a symbol level of the PAM4 signal 651, the buffer chip 610 may remove a timing skew (for example, Ata (see FIG. 12A)) between the data signal DQx of the NVM11 chip and the data signal DQx of the NVM12 chip, so that the edge of the data signal DQx of the NVM11 chip is aligned with the edge of the data signal DQx of the NVM12 chip. The divider circuit 613 may receive the read enable signal nRE which toggles and is transferred from the memory controller 110 controlling a read operation of the memory device 120 and may provide an internal read enable signal nRE_int having a frequency which is lower than that of the read enable signal nRE. For example, the divider circuit 613 may provide the internal read enable signal nRE_int having a 1/2 frequency of a frequency of the read enable signal nRE. The internal read enable signal nRE_int may be provided to a first delay circuit 614 outputting a first read enable signal nRE_N1 and a second delay circuit 615 outputting a second read enable signal nRE_N2.

FIGS. 12A, 12B, 13A, 13B, 14A, 14B, 15A, and 15B are timing diagrams describing a timing skew between non-volatile memory devices of FIG. 3. In FIGS. 12A, 12B, 13A, 13B, 14A, 14B, 15A, and 15B, a command may be issued to the memory device 120 by the memory controller 110, and an operation described below may be performed. In the following description, an issued command and a detailed operation of issuing a certain command may be omitted for conciseness. In timing diagrams described in the following embodiments, the abscissa axis represents a time, the ordinate axis represents a voltage level, and the drawing is not illustrated at a constant rate.

Referring to FIGS. 3 and 12A, at a time ta1, a first read enable signal nRE_N1 of the NVM11 chip and a second read enable signal nRE_N2 of the NVM12 chip may be provided to the memory device 120. The NVM11 chip may generate a data strobe signal DQS which starts to toggle at a time ta2 from the time ta1 which is a toggling start time of the first read enable signal nRE_N1 and may transfer a data signal DQx to the signal line 656, based on a toggle timing of the data strobe signal DQS. The NVM12 chip may generate a data strobe signal DQS which starts to toggle at a time ta3 from the time ta1 which is a toggling start time of the second read enable signal nRE_N2 and may transfer a data signal DQx to the signal line 656, based on a toggle timing of the data strobe signal DQS.

A timing skew Δta may occur between the time ta2 at which the data signal DQx of the NVM11 chip is output and the time ta3 at which the data signal DQx of the NVM12 chip is output. The timing skew Δta between the data signal DQx of the NVM11 chip and the data signal DQx of the NVM12 chip may be identified by the control circuit 616.

The memory controller 110 may perform memory training on the memory device 120. The buffer chip 610 may perform data training on the NVM chips NVM11 and NVM12 of the memory device 120 in response to a training command of the memory controller 110. Based on the data training, the edge of the data signal DQx of the NVM11 chip is aligned with the edge of the data signal DQx of the NVM12 chip. In the data training, the control circuit 616 of the buffer chip 610 may receive determination values A, B, and C of the receiver circuit 611 and may control the first delay circuit 614 and the second delay circuit 615, based on a difference between the determination values A, B, and C and expected values.

In the buffer chip 610, the second delay circuit 615 may control a time at which the second read enable signal nRE_N2 is output by the control circuit 616, as illustrated in FIG. 12B. For example, using the second delay circuit 615, the time at which the second read enable signal nRE_N2 starts toggling is shifted from the time ta1 to a time ta0, which is earlier than the time ta1. The NVM12 chip may generate a data strobe signal DQS which starts to toggle at the time ta2 in response to the second read enable signal nRE_N2 which starts toggling at the time ta0. The NVM12 chip may transfer a data signal DQx to the signal line 656, based on a toggle timing of the data strobe signal DQS. At the time ta2, the edge of the data signal DQx of the NVM11 chip and the edge of the data signal DQx of the NVM12 chip each transferred to the signal line 656 may be aligned with each other. Accordingly, the timing skew Δta of the signal line 656 may be removed.

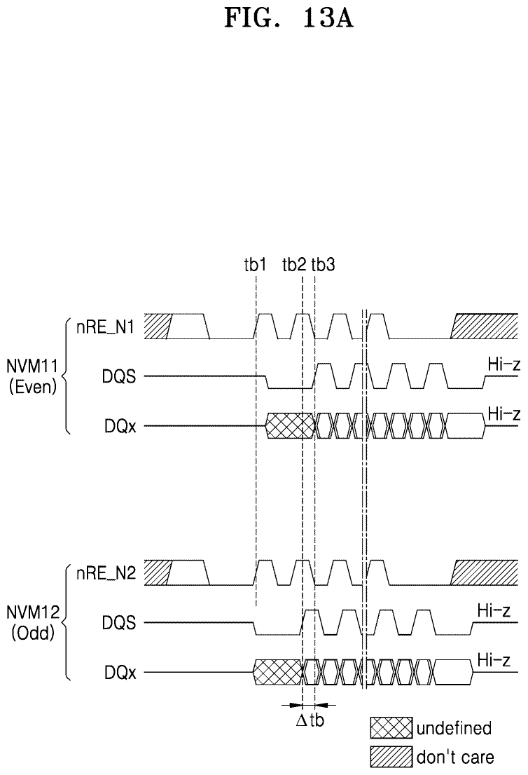

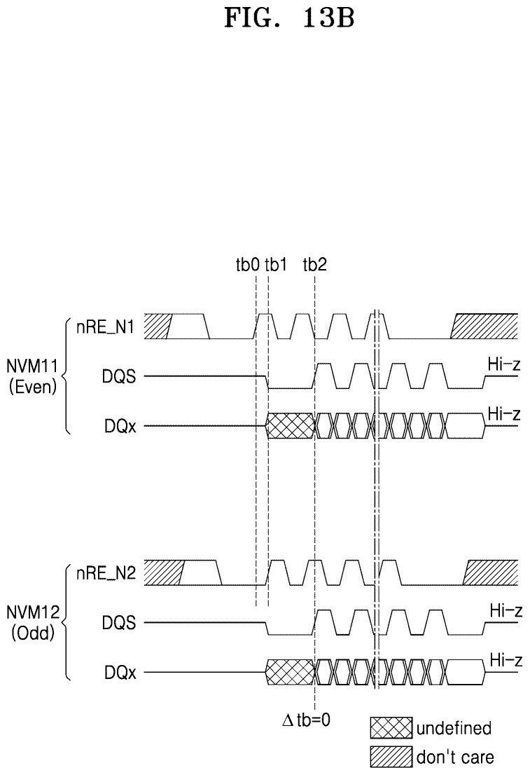

Referring to FIGS. 3 and 13A, at a time tb1, the first read enable signal nRE_N1 of the NVM11 chip and the second read enable signal nRE_N2 of the NVM12 chip may be provided to the memory device 120. The NVM11 chip may generate a data strobe signal DQS which starts to toggle at a time tb3 in response to the first read enable signal nRE_N1 which starts toggling at the time tb1. The NVM11 chip may transfer a data signal DQx to the signal line 656, based on a toggle timing of the data strobe signal DQS. The NVM12 chip may generate a data strobe signal DQS which starts to toggle at a time tb2 in response to the second read enable signal nRE_N2 which starts toggling at the time tb1. The NVM12 chip may transfer a data signal DQx to the signal line 656, based on a toggle timing of the data strobe signal DQS.

A timing skew Δtb may occur between the time tb2 at which the data signal DQx of the NVM12 chip is output and the time tb3 at which the data signal DQx of the NVM11 chip is output. The timing skew Δtb between the data signal DQx of the NVM11 chip and the data signal DQx of the NVM12 chip may be identified by the control circuit 616. The control circuit 616, as illustrated in FIG. 13B, may control the first delay circuit 614 to adjust a time at which the first read enable signal nRE_N1 of the NVM11 chip is output. For example, using the first delay circuit 614, the time at which the first read enable signal nRE_N1 starts toggling is shifted from time tb1 to a time tb0, which is earlier than the time tb1. The NVM11 chip may generate a data strobe signal DQS which starts to toggle at the time tb2 in response to the first read enable signal nRE_N1 which starts toggling at the time tb0. The NVM11 chip may transfer a data signal DQx to the signal line 656, based on a toggle timing of the data strobe signal DQS. At the time tb2, the edge of the data signal DQx of the NVM11 chip may be aligned with the edge of the data signal DQx of the NVM12 chip, and thus, the timing skew Δtb may be removed.

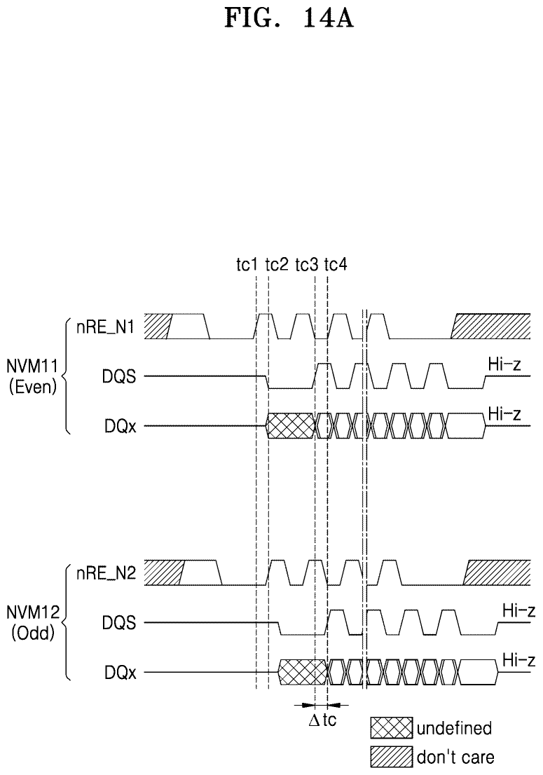

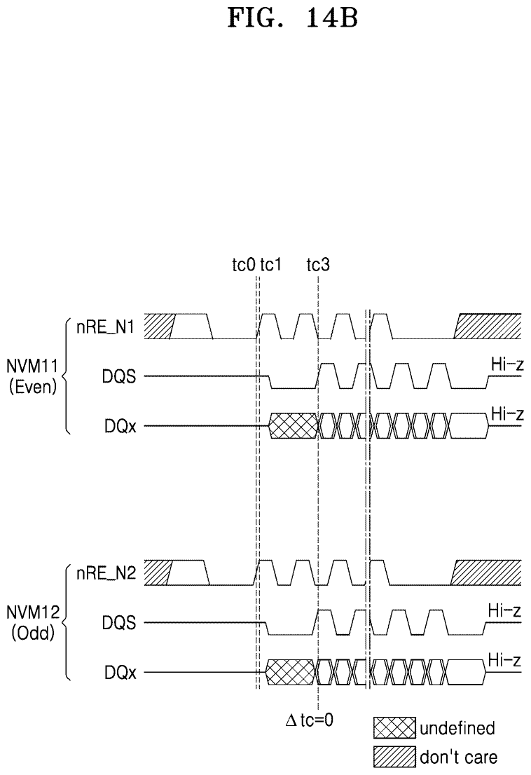

Referring to FIGS. 3 and 14A, at a time tc1, the first read enable signal nRE_N1 of the NVM11 chip may be provided to the memory device 120, and at a time tc2, the second read enable signal nRE_N2 of the NVM12 chip may be provided to the memory device 120. The NVM11 chip may generate a data strobe signal DQS which starts to toggle at a time tc3 in response to the first read enable signal nRE_N1 which starts toggling at the time tc1 and may transfer a data signal DQx to the signal line 656, based on a toggle timing of the data strobe signal DQS. The NVM12 chip may generate a data strobe signal DQS which starts to toggle at a time tc4 in response to the second read enable signal nRE_N2 which starts toggling at the time tc2 and may transfer a data signal DQx to the signal line 656, based on a toggle timing of the data strobe signal DQS.

A timing skew Δtc may occur between the time tc3 at which a data signal DQx of the NVM11 chip is output and the time tc4 at which a data signal DQx of the NVM12 chip is output. The timing skew Δtc between the data signal DQx of the NVM11 chip and the data signal DQx of the NVM12 chip may be identified by the control circuit 616. The control circuit 616, as illustrated in FIG. 14B, may control the second delay circuit 615 to adjust a time at which the second read enable signal nRE_N2 of the NVM12 chip is output. Using the second delay circuit 615, the time at which the second read enable signal nRE_N2 starts toggling is shifted from the time tc2 to a time tc0 time which is earlier than the time tc2. The NVM12 chip may generate a data strobe signal DQS which starts to toggle at the time tc3 in response to the second read enable signal nRE_N2 which starts toggling at the time tc0 and may transfer a data signal DQx to the signal line 656, based on a toggle timing of the data strobe signal DQS. At the time tc3, the edge of the data signal DQx of the NVM11 chip may be aligned with the edge of the data signal DQx of the NVM12 chip, and thus, the timing skew Δtc may be removed.

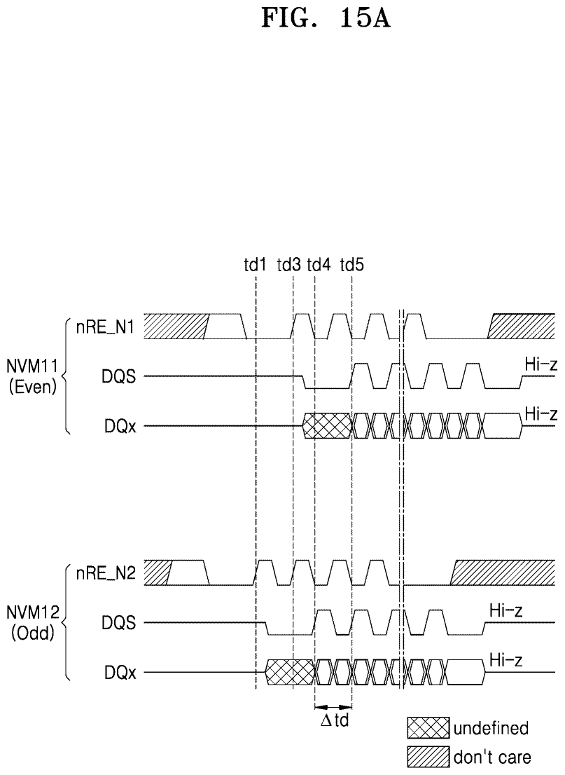

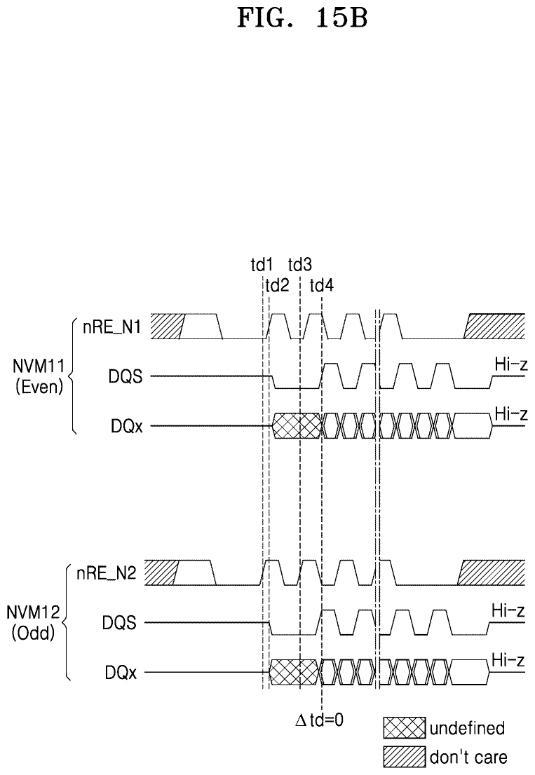

Referring to FIGS. 3 and 15A, at a time td1, the second read enable signal nRE_N2 of the NVM12 chip may be provided to the memory device 120, and at a time td3, the first read enable signal nRE_N1 of the NVM11 chip may be provided to the memory device 120. The NVM12 chip may generate a data strobe signal DQS which starts to toggle at a time td4 in response to the second read enable signal nRE_N2 which starts toggling at the time td1 and may transfer a data signal DQx to the signal line 656, based on a toggle timing of the data strobe signal DQS. The NVM11 chip may generate a data strobe signal DQS which starts to toggle at a time td5 in response to the first read enable signal nRE_N1 which starts toggling at the time td3 and may transfer a data signal DQx to the signal line 656, based on a toggle timing of the data strobe signal DQS.

A timing skew Δtd may occur between the time td4 at which the data signal DQx of the NVM12 chip is output and the time td5 at which the data signal DQx of the NVM11 chip is output. The timing skew Δtd between the data signal DQx of the NVM12 chip and the data signal DQx of the NVM11 chip may be identified by the control circuit 616. The control circuit 616, as illustrated in FIG. 15B, may control the first delay circuit 614 to adjust a time at which the first read enable signal nRE_N1 of the NVM11 chip is output. Using the first delay circuit 614, the time at which the first read enable signal nRE_N1 starts toggling is shifted from the time td3 to a time td2, which is earlier than the time td3. The NVM11 chip may generate a data strobe signal DQS which starts to toggle at the time td4 in response to the first read enable signal nRE_N1 which starts toggling at the time td2 and may transfer a data signal DQx to the signal line 656, based on a toggle timing of the data strobe signal DQS. At the time td4, the edge of the data signal DQx of the NVM11 chip may be aligned with the edge of the data signal DQx of the NVM12 chip, and thus, the timin skew Δtd may be removed.

In some embodiments, a time at which the data strobe signal DQS of the NVM11 chip is generated may be changed by a delay-controlled first read enable signal nRE_N1, and a time at which the data strobe signal DQS of the NVM12 chip is generated may be changed by a delay-controlled second read enable signal nRE_N2. The data signal DQx of the NVM11 chip may be output based on the time-changed data strobe signal DQS of the NVM11 chip, and the data signal DQx of the NVM12 chip may be output based on the time-changed data strobe signal DQS of the NVM12 chip. Based on such repeated operations, the output time of a data signal DQx of the NVM12 chip and the output time of a data signal DQx of the NVM12 chip may be adjusted to be equal to each other. This may denote that the edge of a data signal DQx of the NVM11 chip based on the delay-controlled first read enable signal nRE_N1 is aligned with the edge of a data signal DQx of the NVM12 chip based on the delay-controlled second read enable signal nRE_N2.

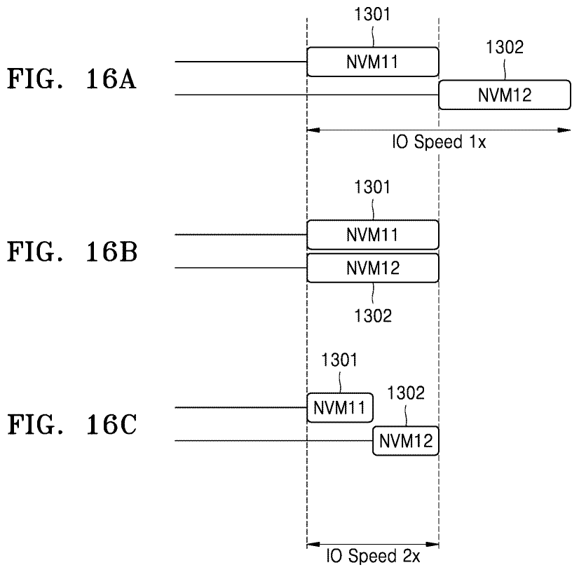

FIGS. 16A, 16B, and 16C are diagrams describing a read performance of the memory system 600 of FIG. 3.

In a comparative example where the buffer chip 610 of the memory system 600 is not implemented, as illustrated in FIG. 16(a), the memory controller 110 may sequentially receive data 1301 of an NVM11 chip and data 1302 of an NVM12 chip each read from the memory device 120. According to embodiments of the present disclosure, when the memory system 600 includes the buffer chip 610, the buffer chip 610 of the memory system 600, as illustrated in FIG. 16(b), may receive the data 1301 of the NVM11 chip and the data 1302 of the NVM12 chip, which are simultaneously transferred to the signal line 656. A PAM4 signal 651 where the data 1301 of the NVM11 chip and the data 1302 of the NVM12 chip are encoded (i.e., are combined) may be carried in the signal line 656. The buffer chip 610 may receive the PAM4 signal 651 of the signal line 656 and may determine a symbol level of the PAM4 signal 651 to generate a 2-bitstream signal corresponding to a PAM4 symbol level (i.e., recover the data 1301 of the NVM11 chip and the data 1302 of the NVM12). The buffer chip 610, as illustrated in FIG. 16(c), may align the data 1301 of the NVM11 chip with the data 1302 of the NVM12 chip for transfer to the memory controller 110. When a data input/output (I/O) speed is 1× in FIG. 16(a), the memory system 600 may have a double data I/O speed (i.e., 2× data I/O speed) in FIG. 16(c). Accordingly, the memory system 600 may increase a data I/O speed to improve read performance.

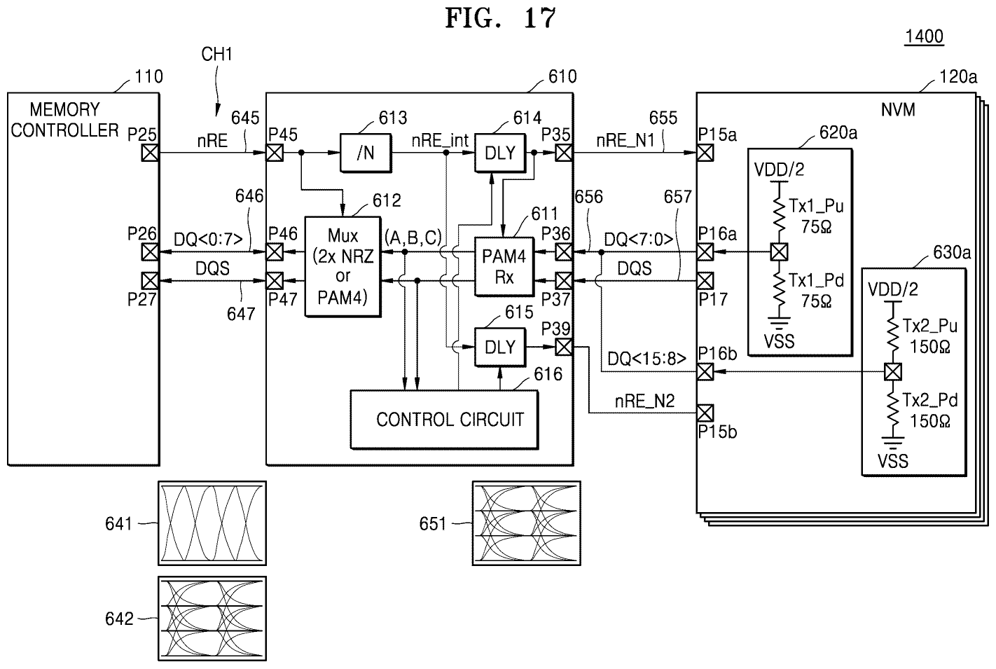

FIG. 17 is a diagram describing a memory system 1400 according to embodiments.

Comparing with the memory system 100 of FIG. 3, the memory system 1400 of FIG. 17 may have a difference in that a memory device 120a is implemented with a multi-chip package (MCP). Hereinafter, a subscript (for example, a of 120a, a of 620a, and a of 630a) attached to a reference numeral may be for dividing a plurality of circuits having the same function. Descriptions of the memory system 1400 which is the same as or similar to the descriptions of FIG. 3 are omitted.

Referring to FIG. 17, in the memory system 1400, the memory device 120a may transfer sixteen data signals DQ<15:0> to a signal line 656. The sixteen data signals DQ<15:0> may be divided into eight upper data signals DQ<15:8> and eight lower data signals DQ<7:0>. The memory device 120a may include a P16a pin which outputs lower data signals DQ<7:0> and a P16b pin which outputs the upper data signals DQ<15:8>. The P16a pin may be configured with eight pins corresponding to the eight lower data signals DQ<7:0> and the P16b pin may be configured with eight pins corresponding to the eight upper data signals DQ<15:8>. The memory device 120a may include a P15a pin to which a first read enable signal nRE_N1 is transferred and a P15b pin to which a second read enable signal nRE_N2 is transferred. The first read enable signal nRE_N1 may be a read enable signal corresponding to the eight lower data signals DQ<7:0>, and the second read enable signal nRE_N2 may be a read enable signal corresponding to the eight upper data signals DQ<15:8>.

The memory device 120a may include a first output driver 620a connected to the P16a pin and a second output driver 630a connected to the P16b pin. The strength of the first output driver 620a and the strength of the second output driver 630a may be differently set. For example, an equivalent circuit of the first output driver 620a may be modeled with a first pull-up resistor Tx1_Pu and a first pull-down resistor Tx1_Pd each connected between a first voltage level VDD/2 and a second voltage level VSS. The first pull-up resistor Tx1_Pu may be set to have a resistance value of about 75Ω, and the first pull-down resistor Tx1_Pd may be set to have a resistance value of about 75Ω. An equivalent circuit of the second output driver 630a may be modeled with a second pull-up resistor Tx2_Pu and a second pull-down resistor Tx2_Pd each connected between the first voltage level VDD/2 and the second voltage level VSS. The second pull-up resistor Tx2_Pu may be set to have a resistance value of about 150Ω, and the second pull-down resistor Tx2_Pd may be set to have a resistance value of about 150Ω.

The first output driver 620a including the first pull-up resistor Tx1_Pu and the first pull-down resistor Tx1_Pd may drive the lower data signals DQ<7:0>, and the second output driver 630a including the second pull-up resistor Tx2_Pu and the second pull-down resistor Tx2_Pd may drive the upper data signals DQ<15:8>. Each of the lower data signals DQ<7:0> and each of the upper data signals DQ<15:8> in the memory device 120a may be combined with each other to generate a composite signal. For example, the data signal DQ7 may be combined with the data signal DQ15 to generate a composite signal thereof. Similarly, the data signal DQ0 may be combined with the data signal DQ8 to generate a composite signal thereof. The composite signal may be carried through the signal line 656 between the P16a pin and the P16b pin of the memory device 120a, and may be provided to the P36 pin of the buffer chip 610. The composite signals of the lower data signals DQ<7:0> and the upper data signals DQ<15:8> may be generated as the PAM4 signal 651 of the signal line 656 described above with reference to FIG. 4. In this case, it may be understood that the lower data signals DQ<7:0> corresponds to a data signal of the NVM11 chip of FIG. 4, and the upper data signals DQ<15:8> corresponds to a data signal of the NVM12 chip. The composite signals of the lower data signals DQ<7:0> and the upper data signals DQ<15:8> may be generated as the PAM4 signal 651 of the signal line 656 described above with reference to FIGS. 4 to 9.

In some embodiments, the first output driver 620a including the first pull-up resistor Tx1_Pu and the first pull-down resistor Tx1_Pd may drive the upper data signals DQ<15:8>, and the second output driver 630a including the second pull-up resistor Tx2_Pu and the second pull-down resistor Tx2_Pd may drive the lower data signals DQ<7:0>. Each of the lower data signals DQ<7:0> and a corresponding one of the upper data signals DQ<15:8> in the memory device 120a may be combined with each other to generate a corresponding composite signal. The composite signal may be carried through the signal line 656. It may be understood that the upper data signals DQ<15:8> correspond to the data signal of the NVM11 chip of FIG. 4, and the lower data signals DQ<7:0> corresponds to the data signal of the NVM12 chip. The composite signals of the lower data signals DQ<7:0> and the upper data signals DQ<15:8> may be generated as the PAM4 signal 651 of the signal line 656 described above with reference to FIGS. 4 to 9.

In the PAM4 signal 651 of the signal line 656, a symbol level of the PAM4 signal 651 may be determined by the receiver circuit 611 of the buffer chip 610 described above with reference to FIGS. 10 to 12 and may be generated as a 2-bitstream signal corresponding to the PAM4 symbol level. The multiplexer circuit 612 of the buffer chip 610 may align the generated 2-bitstream signal with a data signal corresponding to the lower data signals DQ<7:0> and a data signal corresponding to the upper data signals DQ<15:8>. The buffer chip 610 may transfer the lower data signals DQ<7:0> and the upper data signals DQ<15:8> of the memory device 120 to the P26 pin of the memory controller 110 through the P46 pin.

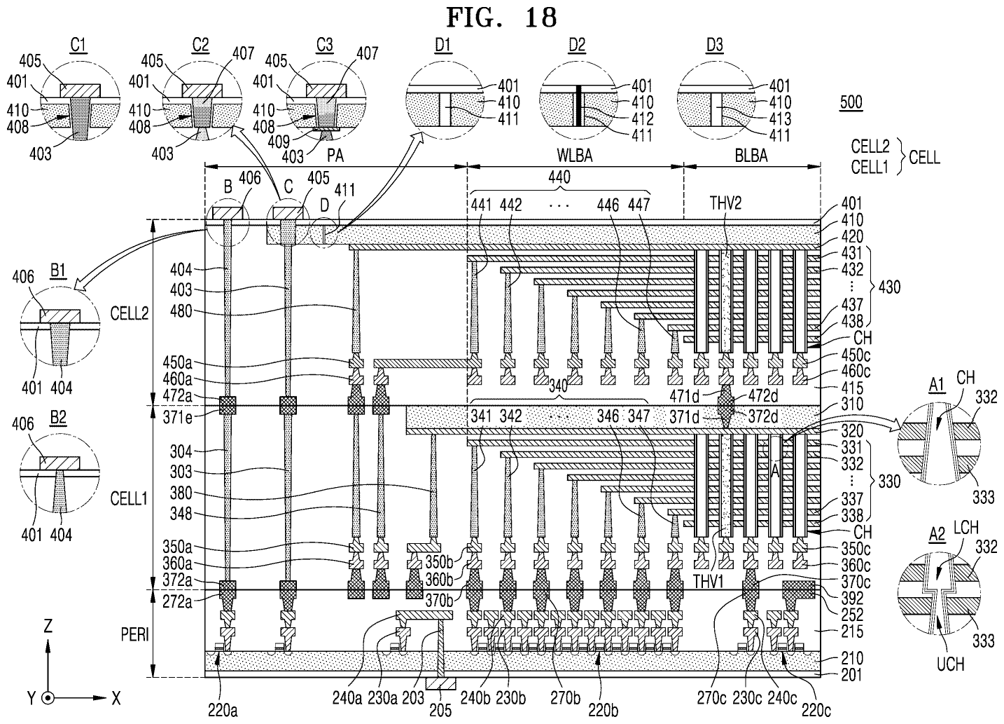

FIG. 18 is a view illustrating a memory device 500 according to some embodiments of the inventive concepts.

Referring to FIG. 18, the memory device 500 may have a chip-to-chip (C2C) structure. At least one upper chip including a cell region and a lower chip including a peripheral circuit region PERI may be manufactured separately, and then, the at least one upper chip and the lower chip may be connected to each other by a bonding method to realize the C2C structure. For example, in the bonding method, a bonding metal pattern formed in an uppermost metal layer of the upper chip is bonded to a bonding metal pattern formed in an uppermost metal layer of the lower chip for electrical connection. For example, in a case in which the bonding metal patterns are formed of copper (Cu), the bonding method may be a Cu-Cu bonding method. In some embodiments, the bonding metal patterns may be formed of aluminum (Al) or tungsten (W).

The memory device 500 may include the at least one upper chip including the cell region. For example, as illustrated in FIG. 18, the memory device 500 may include two upper chips. However, the number of the upper chips is not limited thereto. In the case in which the memory device 500 includes the two upper chips, a first upper chip including a first cell region CELL1, a second upper chip including a second cell region CELL2 and the lower chip including the peripheral circuit region PERI may be manufactured separately, and then, the first upper chip, the second upper chip and the lower chip may be connected with each other by the bonding method to manufacture the memory device 500. The first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on an orientation thereof before each of the first and second upper chips is turned over. In other words, an upper portion of the lower chip may mean an upper portion defined based on a Z-axis direction, and the upper portion of each of the first and second upper chips may mean an upper portion defined based on a direction opposite to the Z-axis direction in FIG. 18. However, embodiments of the inventive concepts are not limited thereto. In certain embodiments, one of the first upper chip and the second upper chip may be turned over and then may be connected to a corresponding chip by the bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate 210 and a plurality of circuit elements 220a, 220b and 220c formed on the first substrate 210. An interlayer insulating layer 215 including one or more insulating layers may be provided on the plurality of circuit elements 220a, 220b and 220c, and a plurality of metal lines electrically connected to the plurality of circuit elements 220a, 220b and 220c may be provided in the interlayer insulating layer 215. For example, the plurality of metal lines may include first metal lines 230a, 230b and 230c connected to the plurality of circuit elements 220a, 220b and 220c, and second metal lines 240a, 240b and 240c formed on the first metal lines 230a, 230b and 230c. The plurality of metal lines may be formed of at least one of various conductive materials. For example, the first metal lines 230a, 230b and 230c may be formed of tungsten having a relatively high electrical resistivity, and the second metal lines 240a, 240b and 240c may be formed of copper having a relatively low electrical resistivity.

The first metal lines 230a, 230b and 230c and the second metal lines 240a, 240b and 240c are illustrated and described in the present embodiments. However, embodiments of the inventive concepts are not limited thereto. In certain embodiments, at least one or more additional metal lines may be formed on the second metal lines 240a, 240b and 240c. In this case, the second metal lines 240a, 240b and 240c may be formed of aluminum, and at least some of the additional metal lines formed on the second metal lines 240a, 240b and 240c may be formed of copper having an electrical resistivity lower than that of aluminum of the second metal lines 240a, 240b and 240c.

The interlayer insulating layer 215 may be disposed on the first substrate 210 and may include an insulating material such as silicon oxide and silicon nitride.

Each of the first and second cell regions CELL1 and CELL2 may include at least one memory block. The first cell region CELL1 may include a second substrate 310 and a common source line 320. A plurality of word lines 330 (331 to 338) may be stacked on the second substrate 310 in a direction (i.e., the Z-axis direction) perpendicular to a top surface of the second substrate 310. String selection lines and a ground selection line may be disposed on and under the word lines 330, and the plurality of word lines 330 may be disposed between the string selection lines and the ground selection line. Likewise, the second cell region CELL2 may include a third substrate 410 and a common source line 420, and a plurality of word lines 430 (431 to 438) may be stacked on the third substrate 410 in a direction (i.e., the Z-axis direction) perpendicular to a top surface of the third substrate 410. Each of the second substrate 310 and the third substrate 410 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CELL1 and CELL2.

In some embodiments, as illustrated in a region A with an enlarged drawing ‘A1’, the channel structure CH may be provided in the bit line bonding region BLBA and may extend in the direction perpendicular to the top surface of the second substrate 310 to penetrate the word lines 330, the string selection lines, and the ground selection line. The channel structure CH may include a data storage layer, a channel layer, and a filling insulation layer. The channel layer may be electrically connected to a first metal line 350c and a second metal line 360c in the bit line bonding region BLBA. For example, the second metal line 360c may be a bit line and may be connected to the channel structure CH through the first metal line 350c. The bit line 360c may extend in a first direction (e.g., a Y-axis direction) parallel to the top surface of the second substrate 310.

In some embodiments, as illustrated in a region A with an enlarged drawing ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 310 to penetrate the common source line 320 and lower word lines 331 and 332. The lower channel LCH may include a data storage layer, a channel layer, and a filling insulation layer and may be connected to the upper channel UCH. The upper channel UCH may penetrate upper word lines 333 to 338. The upper channel UCH may include a data storage layer, a channel layer, and a filling insulation layer, and the channel layer of the upper channel UCH may be electrically connected to the first metal line 350c and the second metal line 360c. As a length of a channel increases, due to characteristics of manufacturing processes, it may be difficult to form a channel having a substantially uniform width. The memory device 500 according to the present embodiments may include a channel having improved width uniformity by sequentially forming the lower channel LCH and the upper channel UCH.

In the case in which the channel structure CH includes the lower channel LCH and the upper channel UCH as illustrated in the region A with an enlarged drawing ‘A2’, a word line located near to a boundary between the lower channel LCH and the upper channel UCH may be a dummy word line. For example, the word lines 332 and 333 adjacent to the boundary between the lower channel LCH and the upper channel UCH may be the dummy word lines. In this case, data may not be stored in memory cells connected to the dummy word line. Alternatively, the number of pages corresponding to the memory cells connected to the dummy word line may be less than the number of pages corresponding to the memory cells connected to a general word line. A level of a voltage applied to the dummy word line may be different from a level of a voltage applied to the general word line, and thus it is possible to reduce an influence of a non-uniform channel width between the lower and upper channels LCH and UCH on an operation of the memory device.

Meanwhile, the number of the lower word lines 331 and 332 penetrated by the lower channel LCH is less than the number of the upper word lines 333 to 338 penetrated by the upper channel UCH in the region A marked with ‘A2’. However, embodiments of the inventive concepts are not limited thereto. In certain embodiments, the number of the lower word lines penetrated by the lower channel LCH may be equal to or more than the number of the upper word lines penetrated by the upper channel UCH. In addition, structural features and connection relation of the channel structure CH disposed in the second cell region CELL2 may be substantially the same as those of the channel structure CH disposed in the first cell region CELL1.

In the bit line bonding region BLBA, a first through-electrode THV1 may be provided in the first cell region CELL1, and a second through-electrode THV2 may be provided in the second cell region CELL2. As illustrated in FIG. 18, the first through-electrode THV1 may penetrate the common source line 320 and the plurality of word lines 330. In certain embodiments, the first through-electrode THV1 may further penetrate the second substrate 310. The first through-electrode THV1 may include a conductive material. In some embodiments, the first through-electrode THV1 may include a conductive material surrounded by an insulating material. The second through-electrode THV2 may have the same shape and structure as the first through-electrode THV1.

In some embodiments, the first through-electrode THV1 and the second through-electrode THV2 may be electrically connected to each other through a first through-metal pattern 372d and a second through-metal pattern 472d. The first through-metal pattern 372d may be formed at a bottom end of the first upper chip including the first cell region CELL1, and the second through-metal pattern 472d may be formed at a top end of the second upper chip including the second cell region CELL2. The first through-electrode THV1 may be electrically connected to the first metal line 350c and the second metal line 360c. A lower via 371d may be formed between the first through-electrode THV1 and the first through-metal pattern 372d, and an upper via 471d may be formed between the second through-electrode THV2 and the second through-metal pattern 472d. The first through-metal pattern 372d and the second through-metal pattern 472d may be connected to each other by the bonding method.

In addition, in the bit line bonding region BLBA, an upper metal pattern 252 may be formed in an uppermost metal layer of the peripheral circuit region PERI, and an upper metal pattern 392 having the same shape as the upper metal pattern 252 may be formed in an uppermost metal layer of the first cell region CELL1. The upper metal pattern 392 of the first cell region CELL1 and the upper metal pattern 252 of the peripheral circuit region PERI may be electrically connected to each other by the bonding method. In the bit line bonding region BLBA, the bit line 360c may be electrically connected to a page buffer included in the peripheral circuit region PERI. For example, some of the circuit elements 220c of the peripheral circuit region PERI may constitute the page buffer, and the bit line 360c may be electrically connected to the circuit elements 220c constituting the page buffer through an upper bonding metal pattern 370c of the first cell region CELL1 and an upper bonding metal pattern 270c of the peripheral circuit region PERI.

Referring continuously to FIG. 18, in the word line bonding region WLBA, the word lines 330 of the first cell region CELL1 may extend in a second direction (e.g., an X-axis direction) parallel to the top surface of the second substrate 310 and may be connected to a plurality of cell contact plugs 340 (341 to 347). First metal lines 350b and second metal lines 360b may be sequentially connected onto the cell contact plugs 340 connected to the word lines 330. In the word line bonding region WLBA, the cell contact plugs 340 may be connected to the peripheral circuit region PERI through upper bonding metal patterns 370b of the first cell region CELL1 and upper bonding metal patterns 270b of the peripheral circuit region PERI.

The cell contact plugs 340 may be electrically connected to a row decoder included in the peripheral circuit region PERI. For example, some of the circuit elements 220b of the peripheral circuit region PERI may constitute the row decoder, and the cell contact plugs 340 may be electrically connected to the circuit elements 220b constituting the row decoder through the upper bonding metal patterns 370b of the first cell region CELL1 and the upper bonding metal patterns 270b of the peripheral circuit region PERT. In some embodiments, an operating voltage of the circuit elements 220b constituting the row decoder may be different from an operating voltage of the circuit elements 220c constituting the page buffer. For example, the operating voltage of the circuit elements 220c constituting the page buffer may be greater than the operating voltage of the circuit elements 220b constituting the row decoder.

Likewise, in the word line bonding region WLBA, the word lines 430 of the second cell region CELL2 may extend in the second direction (e.g., the X-axis direction) parallel to the top surface of the third substrate 410 and may be connected to a plurality of cell contact plugs 440 (441 to 447). The cell contact plugs 440 may be connected to the peripheral circuit region PERI through an upper metal pattern of the second cell region CELL2 and lower and upper metal patterns and a cell contact plug 348 of the first cell region CELL1.

In the word line bonding region WLBA, the upper bonding metal patterns 370b may be formed in the first cell region CELL1, and the upper bonding metal patterns 270b may be formed in the peripheral circuit region PERT. The upper bonding metal patterns 370b of the first cell region CELL1 and the upper bonding metal patterns 270b of the peripheral circuit region PERI may be electrically connected to each other by the bonding method. The upper bonding metal patterns 370b and the upper bonding metal patterns 270b may be formed of aluminum, copper, or tungsten.

In the external pad bonding region PA, a lower metal pattern 371e may be formed in a lower portion of the first cell region CELL1, and an upper metal pattern 472a may be formed in an upper portion of the second cell region CELL2. The lower metal pattern 371e of the first cell region CELL1 and the upper metal pattern 472a of the second cell region CELL2 may be connected to each other by the bonding method in the external pad bonding region PA. Likewise, an upper metal pattern 372a may be formed in an upper portion of the first cell region CELL1, and an upper metal pattern 272a may be formed in an upper portion of the peripheral circuit region PERI. The upper metal pattern 372a of the first cell region CELL1 and the upper metal pattern 272a of the peripheral circuit region PERI may be connected to each other by the bonding method.

Common source line contact plugs 380 and 480 may be disposed in the external pad bonding region PA. The common source line contact plugs 380 and 480 may be formed of a conductive material such as a metal, a metal compound, and/or doped polysilicon. The common source line contact plug 380 of the first cell region CELL1 may be electrically connected to the common source line 320, and the common source line contact plug 480 of the second cell region CELL2 may be electrically connected to the common source line 420. A first metal line 350a and a second metal line 360a may be sequentially stacked on the common source line contact plug 380 of the first cell region CELL1, and a first metal line 450a and a second metal line 460a may be sequentially stacked on the common source line contact plug 480 of the second cell region CELL2.

Input/output pads 205, 405 and 406 may be disposed in the external pad bonding region PA. Referring to FIG. 18, a lower insulating layer 201 may cover a bottom surface of the first substrate 210, and a first input/output pad 205 may be formed on the lower insulating layer 201. The first input/output pad 205 may be connected to at least one of a plurality of the circuit elements 220a disposed in the peripheral circuit region PERI through a first input/output contact plug 203 and may be separated from the first substrate 210 by the lower insulating layer 201. In addition, a side insulating layer may be disposed between the first input/output contact plug 203 and the first substrate 210 to electrically isolate the first input/output contact plug 203 from the first substrate 210.

An upper insulating layer 401 covering a top surface of the third substrate 410 may be formed on the third substrate 410. A second input/output pad 405 and/or a third input/output pad 406 may be disposed on the upper insulating layer 401. The second input/output pad 405 may be connected to at least one of the plurality of circuit elements 220a disposed in the peripheral circuit region PERI through second input/output contact plugs 403 and 303, and the third input/output pad 406 may be connected to at least one of the plurality of circuit elements 220a disposed in the peripheral circuit region PERI through third input/output contact plugs 404 and 304.

In some embodiments, the third substrate 410 may not be disposed in a region in which the input/output contact plug is disposed. For example, as illustrated in a region ‘B’, the third input/output contact plug 404 may be separated from the third substrate 410 in a direction parallel to the top surface of the third substrate 410 and may penetrate an interlayer insulating layer 415 of the second cell region CELL2 so as to be connected to the third input/output pad 406. In this case, the third input/output contact plug 404 may be formed by at least one of various processes.

In some embodiments, as illustrated in the region B with an enlarged drawing ‘B1’, the third input/output contact plug 404 may extend in a third direction (e.g., the Z-axis direction), and a diameter of the third input/output contact plug 404 may become progressively greater toward the upper insulating layer 401. In other words, a diameter of the channel structure CH described in the region ‘A1’ may become progressively less toward the upper insulating layer 401, but the diameter of the third input/output contact plug 404 may become progressively greater toward the upper insulating layer 401. For example, the third input/output contact plug 404 may be formed after the second cell region CELL2 and the first cell region CELL1 are bonded to each other by the bonding method.

In certain embodiments, as illustrated in the region B with an enlarged drawing ‘B2’, the third input/output contact plug 404 may extend in the third direction (e.g., the Z-axis direction), and a diameter of the third input/output contact plug 404 may become progressively less toward the upper insulating layer 401. In other words, like the channel structure CH, the diameter of the third input/output contact plug 404 may become progressively less toward the upper insulating layer 401. For example, the third input/output contact plug 404 may be formed together with the cell contact plugs 440 before the second cell region CELL2 and the first cell region CELL1 are bonded to each other.

In certain embodiments, the input/output contact plug may overlap with the third substrate 410. For example, as illustrated in a region ‘C’, the second input/output contact plug 403 may penetrate the interlayer insulating layer 415 of the second cell region CELL2 in the third direction (e.g., the Z-axis direction) and may be electrically connected to the second input/output pad 405 through the third substrate 410. In this case, a connection structure of the second input/output contact plug 403 and the second input/output pad 405 may be realized by various methods.

In some embodiments, as illustrated in the region C with an enlarged drawing ‘C1’, an opening 408 may be formed to penetrate the third substrate 410, and the second input/output contact plug 403 may be connected directly to the second input/output pad 405 through the opening 408 formed in the third substrate 410. In this case, as illustrated in the region C with the enlarged drawing ‘C1’, a diameter of the second input/output contact plug 403 may become progressively greater toward the second input/output pad 405. However, embodiments of the inventive concepts are not limited thereto, and in certain embodiments, the diameter of the second input/output contact plug 403 may become progressively less toward the second input/output pad 405.

In certain embodiments, as illustrated in the region C with an enlarged drawing ‘C2’, the opening 408 penetrating the third substrate 410 may be formed, and a contact 407 may be formed in the opening 408. An end of the contact 407 may be connected to the second input/output pad 405, and another end of the contact 407 may be connected to the second input/output contact plug 403. Thus, the second input/output contact plug 403 may be electrically connected to the second input/output pad 405 through the contact 407 in the opening 408. In this case, as illustrated in the region C with the enlarged drawing ‘C2’, a diameter of the contact 407 may become progressively greater toward the second input/output pad 405, and a diameter of the second input/output contact plug 403 may become progressively less toward the second input/output pad 405. For example, the second input/output contact plug 403 may be formed together with the cell contact plugs 440 before the second cell region CELL2 and the first cell region CELL1 are bonded to each other, and the contact 407 may be formed after the second cell region CELL2 and the first cell region CELL1 are bonded to each other.

In certain embodiments illustrated in the region C with an enlarged drawing ‘C3’, a stopper 409 may further be formed on a bottom end of the opening 408 of the third substrate 410, as compared with the embodiments of the region C with the enlarged drawing ‘C2’. The stopper 409 may be a metal line formed in the same layer as the common source line 420. Alternatively, the stopper 409 may be a metal line formed in the same layer as at least one of the word lines 430. The second input/output contact plug 403 may be electrically connected to the second input/output pad 405 through the contact 407 and the stopper 409.

Like the second and third input/output contact plugs 403 and 404 of the second cell region CELL2, a diameter of each of the second and third input/output contact plugs 303 and 304 of the first cell region CELL1 may become progressively less toward the lower metal pattern 371e or may become progressively greater toward the lower metal pattern 371e.

Meanwhile, in some embodiments, a slit 411 may be formed in the third substrate 410. For example, the slit 411 may be formed at a certain position of the external pad bonding region PA. For example, as illustrated in a region ‘D’, the slit 411 may be located between the second input/output pad 405 and the cell contact plugs 440 when viewed in a plan view. Alternatively, the second input/output pad 405 may be located between the slit 411 and the cell contact plugs 440 when viewed in a plan view.

In some embodiments, as illustrated in the region D with an enlarged drawing ‘D1’, the slit 411 may be formed to penetrate the third substrate 410. For example, the slit 411 may be used to prevent the third substrate 410 from being finely cracked when the opening 408 is formed. However, embodiments of the inventive concepts are not limited thereto, and in certain embodiments, the slit 411 may be formed to have a depth ranging from about 60% to about 70% of a thickness of the third substrate 410.

In certain embodiments, as illustrated in the region D with an enlarged drawing ‘D2’, a conductive material 412 may be formed in the slit 411. For example, the conductive material 412 may be used to discharge a leakage current occurring in driving of the circuit elements in the external pad bonding region PA to the outside. In this case, the conductive material 412 may be connected to an external ground line.

In certain embodiments, as illustrated in the region D with an enlarged drawing ‘D3’, an insulating material 413 may be formed in the slit 411. For example, the insulating material 413 may be used to electrically isolate the second input/output pad 405 and the second input/output contact plug 403 disposed in the external pad bonding region PA from the word line bonding region WLBA. Since the insulating material 413 is formed in the slit 411, it is possible to prevent a voltage provided through the second input/output pad 405 from affecting a metal layer disposed on the third substrate 410 in the word line bonding region WLBA.

Meanwhile, in certain embodiments, the first to third input/output pads 205, 405 and 406 may be selectively formed. For example, the memory device 500 may be realized to include only the first input/output pad 205 disposed on the first substrate 210, to include only the second input/output pad 405 disposed on the third substrate 410, or to include only the third input/output pad 406 disposed on the upper insulating layer 401.

In some embodiments, at least one of the second substrate 310 of the first cell region CELL1 or the third substrate 410 of the second cell region CELL2 may be used as a sacrificial substrate and may be completely or partially removed before or after a bonding process. An additional layer may be stacked after the removal of the substrate. For example, the second substrate 310 of the first cell region CELL1 may be removed before or after the bonding process of the peripheral circuit region PERI and the first cell region CELL1, and then, an insulating layer covering a top surface of the common source line 320 or a conductive layer for connection may be formed. Likewise, the third substrate 410 of the second cell region CELL2 may be removed before or after the bonding process of the first cell region CELL1 and the second cell region CELL2, and then, the upper insulating layer 401 covering a top surface of the common source line 420 or a conductive layer for connection may be formed.

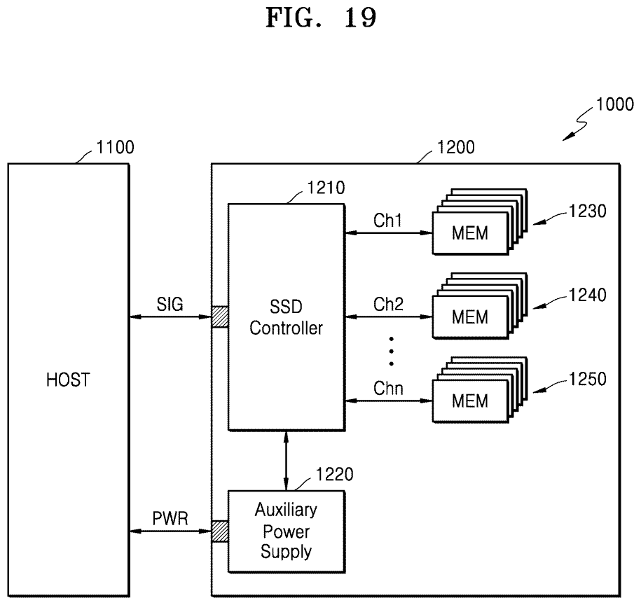

FIG. 19 is a block diagram illustrating an example where a memory system according to embodiments is applied to a solid state drive (SSD) system 1000.

Referring to FIG. 19, the SSD system 1000 may include a host 1100 and an SSD 1200. The SSD 1200 may transmit or receive a signal to or from the host 1100 through a signal connector and may be supplied with power through a power connector. The SSD 1200 may include an SSD controller 1210, an auxiliary power supply 1220, and memory devices 1230, 1240, and 1250. The memory devices 1230, 1240, and 1250 may each be a vertical-stack NAND flash memory device. In this case, the SSD 1200 may be implemented by using the embodiments described above with reference to FIGS. 1 to 18.

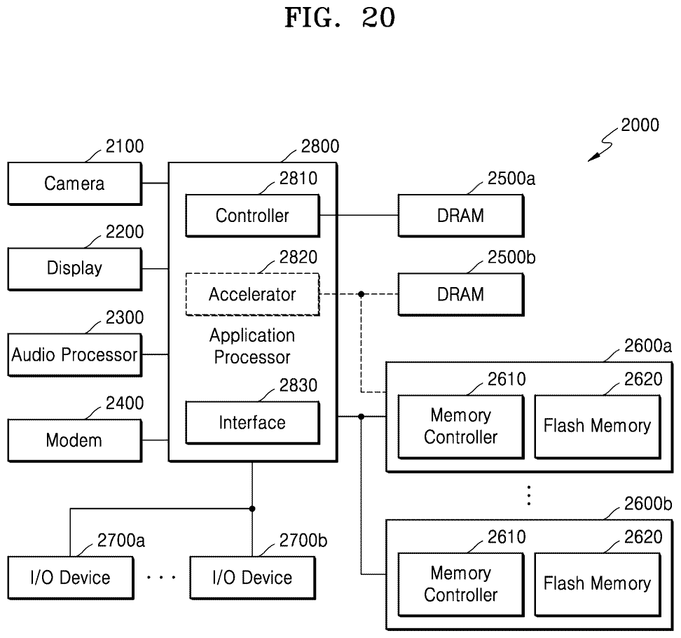

FIG. 20 is a block diagram of a system 2000 for describing an electronic device including a memory system according to embodiments.

Referring to FIG. 20, the system 2000 may include a camera 2100, a display 2200, an audio processor 2300, a modem 2400, DRAMs 2500a and 2500b, flash memories 2600a and 2600b, I/O devices 2700a and 2700b, and an application processor (hereinafter referred to as an AP) 2800. The system 2000 may be implemented with a laptop computer, a mobile phone, a smartphone, a tablet personal computer (PC), a wearable device, a healthcare device, or an Internet of things (IoT) device. Also, the system 2000 may be implemented with a server or a PC.

The camera 2100 may capture a still image or a moving image and may store captured image/video data or may transmit the captured image/video data to the display 2200, based on control by a user. The audio processor 2300 may process audio data included in content of a network or the flash memories 2600a and 2600b. The modem 2400 may modulate and transmit a signal so as to transmit or receive wired/wireless data, and a receiving side may perform demodulation for recovering to an original signal. The I/O devices 2700a and 2700b may include devices, providing a digital input and/or output function, such as a storage or universal serial bus (USB), a digital camera, a secure digital (SD) card, a digital versatile disc (DVD), a network adapter, and a touch screen.

The AP 2800 may control an overall operation of the system 2000. The AP 2800 may include a control block 2810, an accelerator block or an accelerator chip 2820, and an interface block 2830. The AP 2800 may control the display 2200 so that the display 2200 displays a portion of the content stored in the flash memories 2600a and 2600b. When a user input is received through the I/O devices 2700a and 2700b, the AP 2800 may perform a control operation corresponding to a user input. The AP 2800 may include an accelerator block which is a dedicated circuit for an artificial intelligence (AI) data operation, or may include an accelerator chip 2820 independently of the AP 2800. The DRAM 2500B may be additionally equipped in the accelerator block or the accelerator chip 2820. The accelerator may be a function block which technically performs a certain function of the AP 2800 and may include a graphics processing unit (GPU) which is a function block of technically performing graphics data processing, a neural processing unit (NPU) which is a function block of technically performing AI calculation and inference, and a data processing unit (DPU) which is a function block of technically performing data transfer. In an embodiment, an image captured by the camera 2100 of a user may be signal-processed and stored in the DRAM 2500b, and the accelerator block or an accelerator chip 2820 may perform an AI data operation of recognizing data by using a function used in inference and data stored in the DRAM 2500b.

The system 2000 may include a plurality of DRAMs 2500a and 2500b. The AP 2800 may set a command and a mode register (MRS) based on joint electron device engineering council (JEDEC) standard to control the DRAMs 2500a and 2500b, or may perform communication by setting DRAM interface standard so as to use cyclic redundancy check (CRC)/error correction code (ECC) and a company unique function such as low voltage/high speed/reliability. For example, the AP 2800 may communicate with the DRAM 2500a through an interface based on JEDEC standard such as low power double data rate 4 (LPDDR4) or LPDDR5, and the accelerator block or the accelerator chip 2820 may perform communication by setting DRAM interface standard so as to control the DRAM 2500b for accelerator having a bandwidth which is higher than that of the DRAM 2500a.

In FIG. 20, only the DRAMs 2500a and 2500b are illustrated, but are not limited thereto and when bandwidth, reaction speed, and voltage conditions of the AP 2800 or the accelerator chip 2820 are satisfied, all memories such as phase-change random access memory (PRAM), static random access memory (SRAM), magnetoresistive random access memory (MRAM), resistive random access memory (RRAM), ferroelectric random access memory (FRAM), and hybrid RAM may be used. The DRAMs 2500a and 2500b may have latency and a bandwidth, which are relatively less than those of the I/O devices 2700a and 2700b or the flash memories 2600a and 2600b. The DRAMs 2500a and 2500b may be initialized at a power-on time of the system 2000 and may be used as a temporary storage, where an operating system (OS) and application data are loaded, or may be used as an execution space for various software codes.

Four fundamental arithmetic operations such as addition/subtraction/multiplication/division, a vector operation, an address operation, or a fast Fourier transform (FFT) operation may be performed in the DRAMs 2500a and 2500b. Also, a function used in inference may be performed in the DRAMs 2500a and 2500b. Here, inference may be performed in a deep learning algorithm using an artificial neural network. The deep learning algorithm may include a training operation of learning a model through various data and an inference operation of recognizing data with the learned model.

The system 2000 may include a plurality of storages or a plurality of flash memories 2600a and 2600b each having a capacity which is greater than that of the DRAMs 2500a and 2500b. The accelerator block or the accelerator chip 2820 may perform a training operation and an AI data operation by using the flash memories 2600a and 2600b. In an embodiment, the flash memories 2600a and 2600b may each include a memory controller 2610 and a flash memory device 2620 may more efficiently perform a training operation and an inference AI data operation each performed by the AP 2800 and/or the accelerator chip 2820 by using an operational device included in the memory controller 2610. The flash memories 2600a and 2600b may store a photograph obtained by the camera 2100, or may store data transmitted over a data network. For example, the flash memories 2600a and 2600b may store augmented reality (AR)/virtual reality (VR), high definition (HD), or ultra high definition (UHD) content.

In the system 2000, the flash memories 2600a and 2600b may include the memory system described above with reference to FIGS. 1 to 15. The flash memories 2600a and 2600b may include a buffer chip connected between the memory device (for example, a non-volatile memory device) and the memory controller described above with reference to FIGS. 1 to 15. The memory device may provide a multi-level signal, where a first data signal output through a first data pin is coupled to a second data signal output through a second data pin, to a first signal line connected to the first data pin and the second data pin. The buffer chip may align an edge of the first data signal with an edge of the second data signal while data training is being performed on the memory device by the memory controller. The buffer chip may receive a multi-level signal of the first signal line, compare the multi-level signal with multiple reference voltage levels, output a comparison result and multiple determination values, recover the multi-level signal to a bitstream corresponding to the first data signal and the second data signal, based on the multiple determination values, and output the recovered bitstream to the memory controller. By using the memory system performing multi-level signaling, a data I/O speed may be enhanced, and read performance may be improved. An improved function of the memory system may be usefully applied to a high-speed communication device and system.

Hereinabove, exemplary embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While the inventive concept has been particularly shown and described with reference to embodiments thereof, it will be understood that various changes in form and details may be made therein without departing from the spirit and scope of the following claims.

What is claimed is:

1. A memory system comprising:
a first memory device including a first data pin and configured to output a first data signal through the first data pin;
a second memory device including a second data pin and configured to output a second data signal through the second data pin, wherein each of the first memory device and the second memory device is a non-volatile memory device;
a memory controller configured to control the first and second memory devices;
a buffer chip connected between the memory controller and each of the first and second memory devices; and
a first signal line connecting the buffer chip to each of the first data pin and the second data pin,
wherein the buffer chip comprises:
a receiver circuit configured to:
receive a multi-level signal from the first signal line, wherein the multi-level signal corresponds to a composite signal of the first data signal and the second data signal,
compare the multi-level signal with multiple reference voltage levels, and
output multiple determination values as a comparison result;
a multiplexer configured to:
recover a bitstream including the first data signal and the second data signal from the multi-level signal based on the multiple determination values, and
output the bitstream to the memory controller; and
a control circuit configured to align an edge of the first data signal carried through the first signal line with an edge of the second data signal carried through the first signal line.

2. The memory system of claim 1,
wherein the buffer chip further comprises:
a first delay circuit configured to control a first timing of a first read enable signal provided to the first memory device by the control circuit; and
a second delay circuit configured to control a second timing of a second read enable signal provided to the second memory device by the control circuit,
wherein the memory controller is configured to perform a data training operation on the first and second memory devices, thereby removing a timing skew between the first timing of the first read enable signal and the second timing of the second read enable signal, and
wherein, during the data training operation is being performed on the first and second memory devices, the control circuit is configured to control the first and second delay circuits to align the edge of the first data signal with the edge of the second data signal.

3. The memory system of claim 2,
wherein the first memory device comprises a first read enable signal pin configured to receive the first read enable signal,
wherein the first memory device is configured to output the first data signal based on the first read enable signal,
wherein the second memory device comprises a second read enable signal pin configured to receive the second read enable signal, and
wherein the second memory device is configured to output the second data signal based on the second read enable signal.

4. The memory system of claim 1,
wherein the first memory device comprises a first output driver configured to output the first data signal,
wherein the second memory device comprises a second output driver configured to output the second data signal, and
wherein a driving strength of the first output driver is different from a driving strength of the second output driver.

5. The memory system of claim 4,
wherein the first output driver includes a first pull-up transistor a first voltage level line and the first data pin and a first pull-down transistor connected between a second voltage level line and the first data pin, and each of the first pull-up transistor and the first pull-down transistor is configured to have a first turn-on resistance of a first resistance value,
wherein the second output driver includes a second pull-up transistor connected between the first voltage level line and the second data pin and a second pull-down transistor connected between the second voltage level line and the second data pin, and each of the second pull-up transistor and the second pull-down transistor is configured to have a second turn-on resistance of a second resistance value, and
wherein the first resistance value is different from the second resistance value.

6. The memory system of claim 5,
wherein the first resistance value is a half of the second resistance value.

7. The memory system of claim 5,
wherein the second resistance value is a half of the first resistance value.

8. A memory system comprising:
a memory device including a plurality of data pins having a first group of first data pins and a second group of second data pins and configured to output a plurality of data signals through the plurality of data pins, the first group of first data pins being configured to output a plurality of lower data signals of the plurality of data signals, and the second group of second data pins being configured to output a plurality of upper data signals of the plurality of data signals;
a memory controller configured to control the memory device;
a buffer chip connected between the memory device and the memory controller; and
a plurality of first signal lines connecting the plurality of data pins to the buffer chip,
wherein each of the plurality of first signal lines connects the buffer chip to each of a corresponding first data pin of the first group of first data pins and a corresponding second data pin of the second group of second data pins,
wherein the buffer chip comprises:
a receiver circuit configured to:
receive a plurality of multi-level signals from the plurality of first signal lines, each of the plurality of multi-level signals corresponding to a composite signal of a correspond lower data signal of the plurality of lower data signals and a corresponding upper data signal of the plurality of upper data signals,
compare each of the plurality of multi-level signals with multiple reference voltage levels, and
output multiple determination values for each of the plurality of multi-level signals as a comparison result;
a multiplexer configured to:
recover each bitstream of a plurality of bitstreams from a corresponding multi-level signal of the plurality of multi-level signals using multiple determination values for the corresponding multi-level signal, each bitstream of the plurality of bitstreams including a corresponding lower data signal of the plurality of lower data signals and a corresponding upper data signal of the plurality of upper data signals, and
output the plurality of bitstreams to the memory controller; and
a control circuit configured to align an edge of each of the plurality of lower data signals carried through a corresponding first signal line of the plurality of first signal lines with an edge of a corresponding upper data of the plurality of upper data signals carried through the corresponding first signal line.

9. The memory system of claim 8,
wherein the buffer chip comprises:
a first delay circuit configured to control a first timing of a first read enable signal determining a time at which each of the plurality of lower data signals is output by the control circuit; and
a second delay circuit configured to control a second timing of a second read enable signal determining a time at which each of the plurality of upper data signals is output by the control circuit,
wherein the memory controller is configured to perform a data training operation on the memory device, thereby removing a timing skew between the first timing of the first read enable signal and the second timing of the second read enable signal, and
wherein, during the data training operation is being performed on the plurality of lower data signals and the plurality of upper data signals, the control circuit is configured to control the first and second delay circuits to align an edge of each of the plurality of lower data signals with an edge of a corresponding upper data signal of the plurality of upper data signals.

10. The memory system of claim 8,
wherein the memory device comprises:
a plurality of first output drivers configured to output the plurality of lower data signals; and
a plurality of second output drivers configured to output the plurality of upper data signals, and
wherein a driving strength of each of the plurality of first output drivers is different from a driving strength of a corresponding second output driver of the plurality of second output drivers.

11. The memory system of claim 10,
wherein each of the plurality of first output drivers includes a first pull-up transistor connected between a first voltage level line and a corresponding first data pin of the the first group of first data pins and a first pull-down transistor connected between a second voltage level line and the corresponding first data pin,
wherein each of the first pull-up transistor and the first pull-down transistor is configured to have a first turn-on resistance of a first resistance value,
wherein each of the plurality of second output drivers include a second pull-up transistor connected between the first voltage level line and a corresponding second data pin of the second group of second data pins and a second pull-down transistor connected between the second voltage level line and the corresponding second data pin,
wherein each of the second pull-up transistor and the second pull-down transistor is configured to have a second turn-on resistance of a second resistance value, and
wherein the first resistance value is different from the second resistance value.

12. The memory system of claim 11,
wherein the first resistance value is a half of the second resistance value.

13. The memory system of claim 11,
wherein the second resistance value is a half of the first resistance value.

14. A method of operating a memory system comprising:
outputting a first data signal through a first data pin of a memory device;
outputting a second data signal through a second data pin of the memory device;
performing a data training operation to remove a timing skew between the first data signal and the second data signal by a memory controller controlling the memory device, thereby aligning an edge of the first data signal with an edge of the second data signal;
receiving a multi-level signal through a first signal line connected to the first data pin and the second data pin by a buffer chip connected between the memory controller and the memory device, wherein the multi-level signal corresponds to a composite signal of the first data signal and the second data signal;
comparing the multi-level signal with multiple reference voltage levels to output multiple determination values by the buffer chip;
recovering a bitstream including the first data signal and the second data signal from the multi-level signal based on the multiple determination values by the buffer chip; and
outputting the bitstream to the memory controller by the buffer chip.

15. The method of claim 14,
wherein the memory device is configured to output a plurality of data signals including a plurality of lower data signals synchronized with a first data strobe signal and a plurality of upper data signals synchronized with a second data strobe signal,
wherein the plurality of lower data signals include the first data signal, and
wherein the plurality of upper data signals include the second data signal.

16. The method of claim 14,
wherein the aligning of the edge of the first data signal with the edge of the second data signal comprises:
controlling a first timing of a first read enable signal determining a time at which the first data signal is output; and
controlling a second timing of a second read enable signal determining a time at which the second data signal is output.

17. The method of claim 14,
wherein the outputting of the first data signal comprises outputting the first data signal by a first output driver of the memory device,
wherein the outputting of the second data signal comprises outputting the second data signal by a second output driver of the memory device, and
wherein a driving strength of the first output driver is different from a driving strength of the second output driver.

18. The method of claim 17,
wherein the first output driver includes a first pull-up transistor a first voltage level line and the first data pin and a first pull-down transistor connected between a second voltage level line and the first data pin, and each of the first pull-up transistor and the first pull-down transistor is configured to have a first turn-on resistance of a first resistance value,
wherein the second output driver includes a second pull-up transistor connected between the first voltage level line and the second data pin and a second pull-down transistor connected between the second voltage level line and the second data pin, and each of the second pull-up transistor and the second pull-down transistor is configured to have a second turn-on resistance of a second resistance value, and
wherein the first resistance value is different from the second resistance value.

19. The method of claim 18,
wherein the first resistance value is a half of the second resistance value.

20. The method of claim 18,
wherein the second resistance value is a half of the first resistance value.
